(19) United States
(12) Patent Application Publication
(10) Pub. No.: US 2026/0057946 A1
(43) Pub. Date: Feb. 26, 2026

(54) STORAGE CONTROLLER FOR DETERMINING OPTIMAL READ PASS OFFSET AND STORAGE DEVICE INCLUDING THE SAME

(71) Applicant: Samsung Electronics Co., Ltd., Suwon-si (KR)

(72) Inventors: Sewoong Lee, Suwon-si (KR); Haedong No, Suwon-si (KR); Youn-Soo Cheon, Suwon-si (KR)

(21) Appl. No.: 19/247,116

(22) Filed: Jun. 24, 2025

(30) Foreign Application Priority Data
Aug. 20, 2024 (KR) 10-2024-0111195

(51) Int. Cl. G11C 16/28; G11C 16/04; G11C 16/08; G11C 16/30

(52) U.S. Cl. CPC G11C 16/28; G11C 16/0483; G11C 16/08; G11C 16/30

(57) ABSTRACT

A storage device includes: a nonvolatile memory device including a plurality of sub-blocks; and a storage controller configured to determine a first optimal read voltage of a first sub-block among the plurality of sub-blocks based on first cell count information obtained by an on chip valley search (OVS) operation for the first sub-block, determine a first optimal read pass offset corresponding to the first optimal read voltage based on a magnitude of the first optimal read voltage, and provide a read command and the first read pass offset of the first sub-block to the nonvolatile memory device for applying a first optimal read pass voltage that corresponds to a difference between a default read pass voltage and the first optimal read pass offset to word lines of the first sub-block while the nonvolatile memory device reads data stored in the second sub-block.

### CROSS-REFERENCE TO RELATED APPLICATION

This application claims priority to Korean Patent Application No. 10-2024-0111195 filed in the Korean Intellectual Property Office on Aug. 20, 2024, the contents of which are incorporated herein by reference in its entirety.

### BACKGROUND

A read operation is an operation that reads data stored in a nonvolatile memory device. A nonvolatile memory device may apply a read voltage to a selected word line connected to selected memory cells and a read pass voltage to an unselected word line connected to unselected memory cells during the read operation. However, since the read pass voltage is a voltage that turns on unselected memory cells, a threshold voltage of unselected memory cells may be changed by the read pass voltage. To prevent the threshold voltage of the unselected memory cells from changing during the read operation, the magnitude of the read pass voltage may need to be adjusted.

### SUMMARY

In general, in some aspects, the present disclosure is directed toward a storage controller that reduces the extent to which a threshold voltage of memory cells changes due to a read pass voltage, and a storage device including the same.

According to some implementations, the present disclosure is directed to a storage device that includes: a nonvolatile memory device including a plurality of sub-blocks; and a storage controller configured to determine a first optimal read voltage of a first sub-block among the plurality of sub-blocks based on first cell count information obtained by an on chip valley search (OVS) operation for the first sub-block, determine a first optimal read pass offset corresponding to the first optimal read voltage based on the magnitude of the first optimal read voltage, and provide a read command and the first read pass offset of the first sub-block to the nonvolatile memory device for applying a first optimal read pass voltage that corresponds to a difference between a default read pass voltage and the first optimal read pass offset to word lines of the first sub-block while the nonvolatile memory device reads data stored in the second sub-block.

According to some implementations, the present disclosure is directed to a memory device that includes: a memory cell array including a plurality of sub-blocks; a voltage generator configured to generate voltages to be applied to a plurality of word lines connected to the plurality of sub-blocks; and a control logic circuit configured to control the voltage generator to receive a plurality of optimal read offset and a plurality of optimal read pass offsets from the outside, apply a first optimal read voltage based on a first optimal read offset among the plurality of optimal read offsets and a first optimal read pass voltage based on a first optimal read pass offset among the plurality of optimal read pass offsets to the first sub-block in response to a first read command for reading data stored in a first sub-block among the plurality of sub-blocks, and apply a second optimal read voltage based on a second optimal read offset, which is greater than the first optimal read offset among the plurality of optimal read offsets and a second optimal read pass voltage based on a second optimal read pass offset, which is greater than the first optimal read pass offset among the plurality of optimal read pass offsets to the second sub-block in response to a second read command for reading data stored in a second sub-block among the plurality of sub-blocks.

According to some implementations, the present disclosure is directed to a storage controller that includes: a buffer memory configured to store a history table including information on an offset of a voltage to be applied to a plurality of sub-blocks included in a nonvolatile memory device; a read level controller configured to determine a first optimal read voltage of a first sub-block among the plurality of sub-blocks based on a result of performing an on chip valley search (OVS) for the first sub-block, and add a first optimal read offset and a first optimal read pass offset corresponding to the magnitude of the first optimal read voltage to the history table; and a read operation controller configured to provide a read command to read data stored in the first sub-block, the first optimal read offset, and the first optimal read pass offset to the nonvolatile memory device in response to a read request for the first sub-block.

### BRIEF DESCRIPTION OF THE DRAWINGS

Example implementations will be more clearly understood from the following detailed description, taken in conjunction with the accompanying drawings.

FIG. 1 is diagram showing of an example of a storage device according to some implementations.

FIG. 2 is a diagram showing an example of a nonvolatile memory device according to some implementations.

FIG. 3 is a diagram showing an example of a memory block including a plurality of sub-blocks according to some implementations.

FIG. 4 is diagram showing an example of a NAND string included in the memory block according to some implementations.

FIG. 5 is a diagram showing examples of changes in threshold voltage distribution of the plurality of memory cells according to some implementations.

FIG. 6 is a diagram showing an example of a storage device performing a read operation according to some implementations.

FIG. 7 is a diagram showing an example of a storage device that determines an optimal read offset and an optimal read pass offset based on an optimal read voltage determined by the OVS operation according to some implementations.

FIG. 8 is a diagram showing an example of a storage device that updates the magnitude of an optimal read voltage according to some implementations.

FIG. 9 is a diagram showing an example of a storage device that updates a history table based on the magnitude of an optimal read voltage according to some implementations.

FIG. 10 is a diagram showing an example of a storage device that updates a history table based on the magnitude of an optimal read voltage according to some implementations.

FIG. 11 is a diagram showing an example of an optimal read pass voltage determined based on the magnitude of an optimal read voltage according to some implementations.

FIG. 12 is a diagram showing an example of a storage controller that provides an optimal read offset and an optimal read pass offset of a sub-block to a nonvolatile memory device in response to a read request according to some implementations.

FIG. 13 is a diagram showing an example of a nonvolatile memory device applying an optimal read voltage and an optimal read pass voltage to a plurality of sub-blocks according to some implementations.

FIG. 14 is a diagram showing an example of a nonvolatile memory device that applies a default read voltage and an optimal read pass voltage to a plurality of sub-block according to some implementations.

FIG. 15 is a diagram showing an example of a nonvolatile memory device applying an optimal read voltage and an optimal read pass voltage to a plurality of sub-blocks according to some implementations.

FIG. 16 is a diagram showing an example of a storage controller that provides an optimal read offset and an optimal read pass offset of a memory block to an nonvolatile memory device in respond to a read request according to some implementations.

FIG. 17 is a diagram showing an example of a nonvolatile memory device applying an optimal read voltage and an optimal read pass voltage to a memory block according to some implementations.

FIG. 18 is a diagram showing an example of a nonvolatile memory device that applies a default read voltage and an open read pass voltage to a memory block according to some implementations.

FIG. 19 is a diagram showing an example of a storage controller that updates a history table according to some implementations.

FIG. 20 is a diagram showing an example of a storage controller that provides an optimal read offset and an optimal read pass offset to a nonvolatile memory device based on a history table according to some implementations.

### DETAILED DESCRIPTION

Hereinafter, example implementations will be explained in detail with reference to the accompanying drawings.

In order to clearly explain the present disclosure, parts that are not related to the description are omitted, and the same reference symbols are used for identical or similar components throughout the specification.

In addition, unless explicitly described to the contrary, the word “comprise”, and variations such as “comprises” or “comprising”, will be understood to imply the inclusion of stated elements but not the exclusion of any other elements.

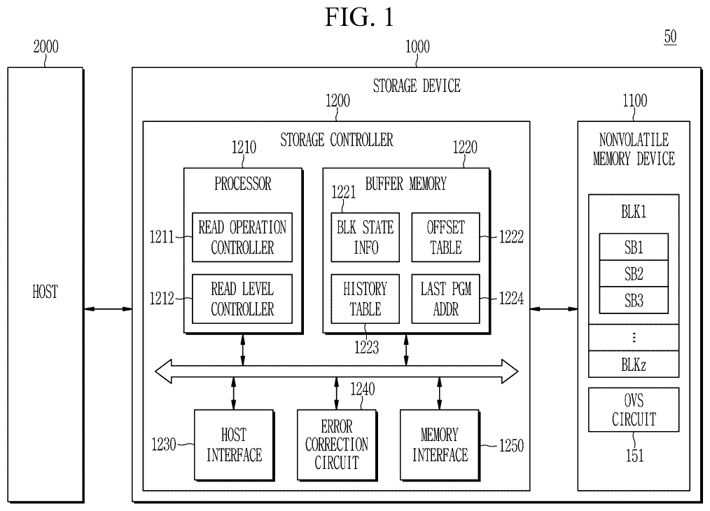

FIG. 1 is a diagram showing an example of a storage device according to some implementations. In FIG. 1, an electron system 50 may include a storage device 1000 and a host 2000. The storage device 1000 may be a device that stores data according to control of the host 2000. In some implementations, the storage device 1000 may be manufactured in the form of a solid state drive (SSD) or a universal flash storage (UFS).

In some implementations, the storage device 1000 may include a nonvolatile memory device 1100 and a storage controller 1200.

In some implementations, the nonvolatile memory device 1100 may store data. The nonvolatile memory device 1100 may operate in response to control of the storage controller 1200. In some implementations, the nonvolatile memory device 1100 may be a NAND flash memory. The nonvolatile memory device 1100 may include a plurality of memory blocks BLK1 to BLKz. Each of the plurality of memory blocks BLK1 to BLKz may include a plurality of sub-blocks. In some implementations, a first memory block BLK1 may include a first sub-block SB1, a second sub-block SB2, and a third sub-block SB3. Each of the plurality of sub-blocks may include a plurality of memory cells that store data.

In some implementations, the nonvolatile memory device 1100 may receive a command and an address from the storage controller 1200, and perform an operation indicated by the command for a region selected by the address. The nonvolatile memory device 1100 may perform a program operation for storing data in a region selected by the address (i.e., write operation), a read operation for reading data, or an erase operation for deleting data.

In some implementations, the nonvolatile memory device 1100 may include on-chip valley search (OVS) circuit 151. The OVS circuit 151 may perform an OVS operation that identifies a threshold voltage of a plurality of memory cells using a plurality of search voltages. The OVS circuit 151 may count the number of memory cells having a threshold voltage that is lower or higher than each of a plurality of search voltages among a plurality of memory cells while performing the OVS operation. The OVS circuit 151 may generate cell count information indicating the number of memory cells and provide the cell count information to the storage controller 1200.

The storage controller 1200 may control overall operations of the storage device 1000.

When power is applied to the storage device 1000, the storage controller 1200 may execute firmware. The firmware may include a host interface layer controlling communication with the host 2000, a flash conversion layer controlling communication between the host 2000 and the nonvolatile memory device 1100, and a memory interface layer controlling communication with the nonvolatile memory device 1100. In the embodiment, the flash translation layer may convert a logical address of the host 2000 into a physical address of the nonvolatile memory device 1100.

The storage controller 1200 may control the nonvolatile memory device 1100 to perform a write operation, a read operation, or an erase operation according to a request of the host 2000. The storage controller 1200 may provide a write command, address, and data to the nonvolatile memory device 1100 during a write operation. The storage controller 1200 may provide a read command and address to the nonvolatile memory device 1100 during a read operation. The storage controller 1200 may provide an erase command and address to the nonvolatile memory device 1100 during an erase operation.

The storage controller 1200 may include a processor 1210, a buffer memory 1220, a host interface 1230, an error correction circuit 1240, and a memory interface 1250. Processor 1210 may control the overall operation of the storage controller 1200. The processor 1210 may generate commands according to the request of the host 2000. The buffer memory 1220 may be used as a cache memory or operating memory of the storage controller 1200.

In some implementations, the buffer memory 1220 may temporarily store data provided from the host 2000 or temporarily store data read from the nonvolatile memory device 1100. For example, the buffer memory 1220 may be a dynamic random access memory (DRAM) or a static random access memory (SRAM). In some implementations, the buffer memory 1220 may be disposed within the storage controller 1200 or may be disposed outside the storage controller 1200.

The buffer memory 1220 may store block state information 1221, an offset table 1222, a history table 1223, and a last program address 1224. The block state information 1221 may include information about the states of the plurality of sub-blocks included in each of the plurality of memory blocks. The block state information 1221 may include information about whether each of the plurality of sub-blocks corresponds to a closed block or an open block. A closed block may be a sub-block including programed memory cells. An open block may be a sub-block containing erased memory cells and programmed memory cells. Memory cells in an erased state may be unprogrammed memory cells.

The offset table 1222 may include information about an optimal read offset and an optimal read pass offset corresponding to the magnitude of the optimal read voltage determined based on cell count information acquired by the OVS operation.

The history table 1223 may include information about optimal read offset and optimal read pass offset for each of the plurality of sub-blocks. The history table 1223 may include information about the optimal read offset and optimal read pass offset determined according to the offset table 1222.

The last program address 1224 may be an address corresponding to the last programmed word line among word lines of a sub-block corresponding to an open block among the plurality of sub-blocks. In some implementations, the next word line following the last programmed word line may be an open word line. The open word line may be a word line that will be programmed after the last programmed word line. An open word line may be a word line to which memory cells in the erased state are connected.

The host interface 1230 may communicate with the host 2000. The host interface 1230 may receive data from the host 2000 or provide data to the host 2000.

The error correction circuit 1240 may perform an encoding operation to generate parity data for data received from the host 2000. The encoded data may be provided to the nonvolatile memory device 1100 through the memory interface 1250. The error correction circuit 1240 may perform an error correction operation on data read from the nonvolatile memory device 1100. The error correction circuit 1240 may perform an error correction operation to correct error bits contained in the data read from the nonvolatile memory device 1100. The error correction circuit 1350 may provide error corrected data to the host 2000 through the host interface 1230.

The memory interface 1250 may communicate with the nonvolatile memory device 1100. The memory interface 1250 may provide data to the nonvolatile memory device 1100 or receive data from the nonvolatile memory device 1100.

The processor 1210 may include a read operation controller 1211 and a read level controller 1212. In some implementations, the read operation controller 1211 may control a read operation for the nonvolatile memory device 1100. In some implementations, the read level controller 1212 may update the history table 1223. The read level controller 1212 may determine the optimal read offset and the optimal read pass offset based on the cell count information obtained from the result of performing the OVS operation, and update the determined optimal read offset and optimal read pass offset in the history table 1223.

The read operation controller 1211 may generate a read command for reading data stored in the nonvolatile memory device 1100. The read operation controller 1211 may control the nonvolatile memory device 1100 to perform a read operation for reading data stored in a sub-block selected from among a plurality of sub-blocks included in the memory block using a default read voltage and a default read pass voltage. In some implementations, the nonvolatile memory device 1100 may apply (provide) a default read voltage to a word line selected from among the plurality of sub-blocks and apply a default read pas voltage to unselected word lines of the selected sub-block and unselected word lines of unselected sub-blocks responding to the read command.

The memory interface 1250 may receive data read from the selected sub-block and provide the data to the error correction circuit 1240. The error correction circuit 1240 may perform an error correction operation for the data read from the selected sub-block. The error correction circuit 1240 may provide error-corrected data to the host 2000 through the host interface 1230 when the error correction operation passes. The error correction circuit 1240 may provide a signal to the read operation controller 1211 indicating that the error correction operation has failed when the error correction operation fails.

When the error correction operation is failed, the read operation controller 1211 may control the nonvolatile memory device 1100 to perform a read operation using a read offset that has a predetermined magnitude difference from the default read voltage. In some implementations, the nonvolatile memory device 1100 may read data stored in the selected sub-block using a read voltage corresponding to a difference between the default read voltage and the read offset, and provide the data to the storage controller 1200.

The read level controller 1212 may update the read offset in the history table 1223 as the optimal read offset when an error correction operation for the data read using the read voltage corresponding to the difference between the default read voltage and the read offset passes.

When the error correction operation for the data read from the selected sub-block using the read voltage corresponding to the difference between the default read voltage and the read offset fails, the read operation controller 1211 may control the nonvolatile memory device 1100 to perform an OVS operation. In some implementations, the nonvolatile memory device 1100 may perform the OVS operation on a selected sub-block and provide cell count information corresponding to a result of performing the OVS operation to the storage controller 1200.

The read level controller 1212 may determine the optimal read voltage of the selected sub-block based on the cell count information. The read level controller 1212 may determine the optimal read offset and the optimal read pass offset corresponding to the magnitude of the optimal read voltage of the selected sub-block based on the offset table 1222. The read level controller 1212 may add the optimal read offset and the optimal read pass offset of the selected sub-block to the history table 1223.

The read operation controller 1211 may read the history table 1223 in response to a read request of the host 2000 for the selected sub-block, and identify the optimal read offset and the optimal read pass offset of the selected sub-block based on the history table 1223. In some implementations, the read operation controller 1211 may control the nonvolatile memory device 1100 to perform a read operation for the selected sub-block according to an optimal read offset and an optimal read pass offset of the selected sub-block in response to the read request. In some implementations, the read operation controller 1211 may provide a read command for reading data stored in the selected sub-block, an optimal read offset and an optimal read pass offset of the selected sub-block to the nonvolatile memory device 1100. The nonvolatile memory device 1100 may read data stored in the selected sub-block responding to the read command, and provide the data to the storage controller 1200. In some implementations, the nonvolatile memory device 1100 may read data stored in a selected sub-block using an optimal read voltage corresponding to a difference between a default read voltage and an optimal read offset and an optimal read pass voltage corresponding to a difference between the default read pass voltage and the optimal read pass offset.

The read operation controller 1211 may identify a sub-block corresponding to an open block among a plurality of sub-blocks included in the memory block based on the block state information 1221. In some implementations, when a sub-block corresponding to an open block from among the plurality of sub-blocks is identified, the read operation controller 1211 may provide a read command for reading data stored in a selected sub-block from among the plurality of sub-blocks, a last program address 1224 of the sub-block corresponding to the open block, and an open read path offset to the nonvolatile memory device 1100. In some implementations, the nonvolatile memory device 1100 may provide an open read pass voltage corresponding to a difference between a default read pass voltage and an open read pass offset to open word lines of the sub-block corresponding to the open block based on the last program address 1224 while reading data stored in the selected sub-block in response to the read command.

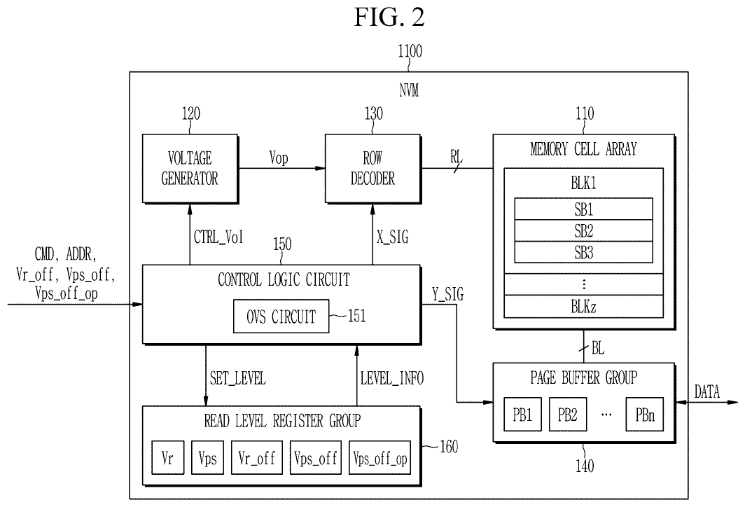

FIG. 2 is a diagram showing an example of the nonvolatile memory device according to some implementations. In FIG. 2, the nonvolatile memory device 1100 may include a memory cell array 110, a voltage generator 120, a row decoder 130, a page buffer group 140, a control logic circuit 150, and a read level register group 160.

The memory cell array 110 may include a plurality of memory blocks BLK1 to BLKz. The plurality of memory blocks BLK1 to BLKz may be connected with the row decoder 130 through row lines RL. The plurality of memory blocks BLK1 to BLKz may be connected with the page buffer group 140 through the bit lines BL. Each of the plurality of memory blocks BLK1 to BLKz may include a plurality of sub-blocks. Each of the plurality of sub-blocks may include a plurality of memory cells. In some implementations, the plurality of memory cells may be nonvolatile memory cells.

The voltage generator 120 may generate operating voltages Vop using an external power source voltage supplied to the nonvolatile memory device 1100. The voltage generator 120 may operate in response to the control of the control logic circuit 150.

The voltage generator 120 may generate operating voltages Vop used for program operations, read operations, and erase operations. For example, the voltage generator 120 may generate a program voltage, a pass voltage, a read voltage, and an erase voltage. The operating voltages Vop may be supplied to the memory cell array 110 by the row decoder 130.

The row decoder 130 may be connected to the memory cell array 110 via row lines RL. The row lines RL may include string selection lines, word lines, and ground selection lines.

The row decoder 130 may operate in response to the control of the control logic circuit 150. The row decoder 130 may receive row signals X_SIG from the control logic circuit 150. In some implementations, the row decoder 130 may select at least one word line from a plurality of word lines based on the row signal X_SIG, and apply the operating voltages Vop provided from the voltage generator 120 to the at least one word line.

The row decoder 130 may apply a program voltage to a selected word line among the plurality of word lines during a program operation and apply a pass voltage at a level lower than the program voltage to unselected word lines. The row decoder 130 may apply a verification voltage to a selected word line during a program verification operation and apply a verification pass voltage of a higher level than the verification voltage to the unselected word lines.

The row decoder 130 may apply a read voltage to a selected word line during a read operation and apply a read pass voltage at a level higher than the read voltage to unselected word lines.

The page buffer group 140 may include a plurality of page buffers PB1 to PBn. The plurality of page buffers PB1 to PBn may be connected to a plurality of memory cells included in the memory cell array 110 via bit lines BL, respectively. The plurality of page buffers PB1 to PBn may operate in response to the control of the control logic circuit 150.

The plurality of page buffers PB1 to PBn may receive data DATA from the storage controller 1200. The plurality of page buffers PB1 to PBn may select at least one bit line among the bit lines BL based on a column signal Y_SIG received from the control logic circuit 150.

The plurality of page buffers PB1 to PBn may transmit data received from the storage controller 1200 to the plurality of memory cells of the memory cell array 110 via the bit lines BL during a program operation. The plurality of memory cells may be programmed according to the received data. The plurality of page buffers PB1 to PBn may sense data stored in the plurality of memory cells through the bit lines BL during a program verification operation.

The plurality of page buffers PB1 to PBn may sense data stored in the memory cells through the bit lines BL during a read operation and store the sensed data in the plurality of page buffers PB1 to PBn.

The read level register group 160 may include a plurality of registers. The read level register group 160 may store information about levels of voltages used in a read operation. In some implementations, the read level register group 160 may store information about a default read voltage Vr and a default read pass voltage Vps. In some implementations, the read level register group 160 may store information on an optimal read offset Vr_off, an optimal read pass offset Vps_off, and an open read pass offset Vps_off_op received from the storage controller 1200. In some implementations, the read level register group 160 may store the optimal read offset Vr_off and the optimal read pass offset Vps_off for each of the plurality of sub-blocks included in each of the plurality of memory blocks.

The control logic circuit 150 may be connected with the voltage generator 120, the row decoder 130, the page buffer group 140, and the read level register group 160.

The control logic circuit 150 may control the overall operation of the nonvolatile memory device 1100. The control logic circuit 150 may control the voltage generator 120, the row decoder 130, the page buffer group 140, and the read level register group 160 to perform operations corresponding to the commands received from the storage controller 1300.

The control logic circuit 150 may include an OVS circuit 151. The OVS circuit 151 may perform an OVS operation for each of the plurality of sub-blocks. The OVS circuit 151 may provide cell count information corresponding to a result of performing the OVS operation to the storage controller 1200.

The control logic circuit 150 may store the optimal read offset Vr_off, the optimal read pass offset Vps_off, and the open read pass offset Vps_off_op received from the storage controller 1200 in the read level register group 160.

The control logic circuit 150 may identify a default read voltage Vr, a default read pass voltage Vps, an optimal read offset Vr_off, and an optimal read pass offset Vps_off stored in a read level register group in response to a read command. In some implementations, the control logic circuit 150 may apply an optimal read voltage corresponding to a difference between the default read voltage Vr and the optimal read offset Vr_off to a selected word line among the word lines of the selected sub-block among the plurality of sub-blocks in response to a read command, and may control the voltage generator 120 and the row decoder 130 to apply an optimal read pass voltage corresponding to a difference between the default read pass voltage Vps and the optimal read pass offset Vps_off to unselected word lines among the word lines of the selected sub-block.

The control logic circuit 150 may control the voltage generator 120 and the row decoder 130 to apply an optimal read pass voltage to unselected word lines of unselected sub-blocks among the plurality of sub-blocks while applying an optimal read voltage to a selected word line of a selected sub-block among the plurality of sub-blocks.

The control logic circuit 150 may control the voltage generator 120 and the row decoder 130 apply an optimal read voltage to a selected word line of a first sub-block SB1, an optimal read pass voltage to unselected word lines of the first sub-block SB1, and an optimal read pass voltage to unselected word lines of an unselected second sub-block SB2 and an unselected third sub-block SB3 in response to a read command for reading data stored in the selected first sub-block SB1.

The control logic circuit 150 may control the voltage generator 120 and the row decoder 130 to apply an open read pass voltage corresponding to a difference between the default read pass voltage Vps and the read pass offset Vps_off_op to open word lines of an open block based on a last program address and an open read pass offset Vps_off_op received from the storage controller 1200.

In some implementations, the control logic circuit 150 may control the voltage generator 120 and the row decoder 130 to apply an open read pass voltage to open word lines of a third sub-block SB3 corresponding to an open block and to apply a default read pass voltage to programmed word lines of the third sub-block SB3 while reading data stored in the selected first sub-block SB1.

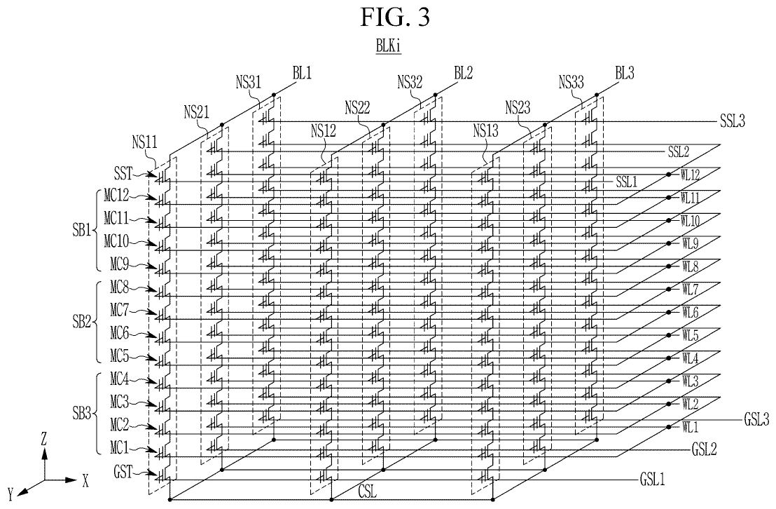

FIG. 3 is a diagram showing an example of a memory block including a plurality of sub-blocks according to some implementations. In FIG. 3, the memory block BLKi of FIG. 3 may be one of the plurality of memory blocks BLK1 to BLKz of FIG. 1 and FIG. 2.

The memory block BLKi may include a plurality of memory cell strings NS11 to NS33 connected between bit lines BL1, BL2, and BL3 and a common source line CSL. Each of the plurality of memory cell strings NS11 to NS33 may include a string selection transistor SST, a plurality of memory cells MC1 to MC12, and a ground selection transistor GST.

The string selection transistor SST may be connected to string selection lines SSL1, SSL2, and SSL3. The plurality of memory cells MC1 to MC12 may be respectively connected to a plurality of word lines WL1 to WL12 stacked on a substrate. The ground selection transistor GST may be connected to ground selection lines GSL1, GSL2, and GSL3. The string selection transistor SST may be connected to the bit lines BL1, BL2, and BL3, and the ground selection transistor GST may be connected to the common source line CSL. Word lines (e.g., WL1) of the same height in the Z-direction are commonly connected to the plurality of memory cell strings NS11 to NS33, and the ground selection lines GSL1, GSL2, and GSL3 and the string selection lines SSL1, SSL2, and SSL3 may be separately connected to the plurality of memory cell strings NS11 to NS33, respectively.

The memory block BLKi may include a plurality of sub-blocks SB1, SB2, and SB3. Each of the plurality of sub-blocks SB1, SB2, and SB3 may be distinguished by the plurality of word lines WL1 to WL12 stacked on the substrate.

In some implementations, a first sub-block SB1 may include memory cells connected to the first to fourth word lines WL1 to WL4 among the memory cells included in the memory block BLKi. A second sub-block SB2 may include memory cells connected to the fifth to eighth word lines WL5 to WL8 among the plurality of memory cells included in the memory block BLKi. A third sub-block SB3 may include memory cells connected to the ninth to twelfth word lines WL9 to WL12 among the memory cells included in the memory block BLKi.

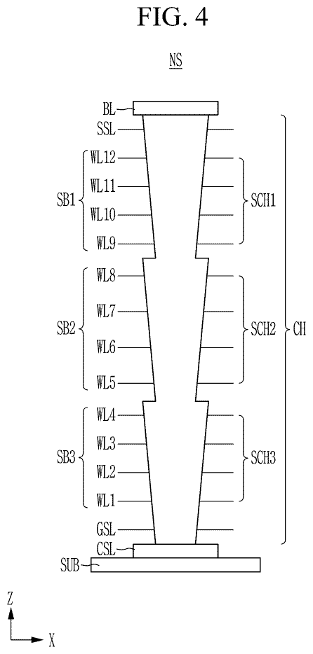

FIG. 4 is a diagram showing an example of a NAND string included in the memory block according to some implementations. In FIG. 4, a memory cell string NS may be one of the plurality of memory cell strings NS11 to NS33 of FIG. 3. The memory cell string NS may include a channel hole CH penetrating the string selection line SSL, the plurality of word lines WL1 to WL12, and the ground selection line GSL. The channel hole CH may be connected between the common source line SL and the bit line BL.

The channel hole CH may include a plurality of sub-channel holes SCH1, SCH2, and SCH3. The channel hole CH may include a plurality of sub-channel holes SCH1, SCH2, and SCH3 vertically (in the Z-axis direction) stacked on the substrate SUB. The plurality of sub-channel holes SCH1, SCH2, and SCH3 may correspond to a plurality of sub-blocks, respectively. The channel hole may include a first sub-channel hole SCH1 corresponding to the first sub-block SB1, a second sub-channel hole SCH2 corresponding to the second sub-block SB2, and a third sub-channel hole SCH3 corresponding to the third sub-block SB3.

The third sub-channel hole SCH1 corresponding to the third sub-block SB3 to which the first to fourth word lines WL1 to WL4 are connected may be disposed on the substrate SUB. The second sub-channel hole SCH2 corresponding to the second sub-block SB2 connected to the fifth to eighth word lines WL5 to WL8 may be disposed on the third sub-channel hole SCH3 corresponding to the third sub-block SB3. The first sub-channel hole SCH1 corresponding to the first sub-block SB1 connected to the ninth to twelfth word lines WL9 to WL12 may be disposed on the second sub-channel hole SCH2 corresponding to the second sub-block SB2.

In some implementations, a plurality of memory cells may be disposed at the intersection of the plurality of word lines WL1 to WL12 and the channel hole CH. The plurality of memory cells connected to the plurality of word lines WL1 to WL12 may be vertically stacked on the substrate SUB.

The plurality of sub-channel holes SCH1, SCH2, and SCH3 may have different widths in the X-axis direction from top to bottom. For example, the width of the third sub-channel hole SCH3 may become narrower as it goes from the fourth word line WL4 to the first word line WL1, the width of the second sub-channel hole SCH2 may become narrower as it goes from the eighth word line WL8 to the fifth word line WL5, and the width of the third sub-channel hole SCH3 may become narrower as it goes from the twelfth word line WL12 to the ninth word line WL9.

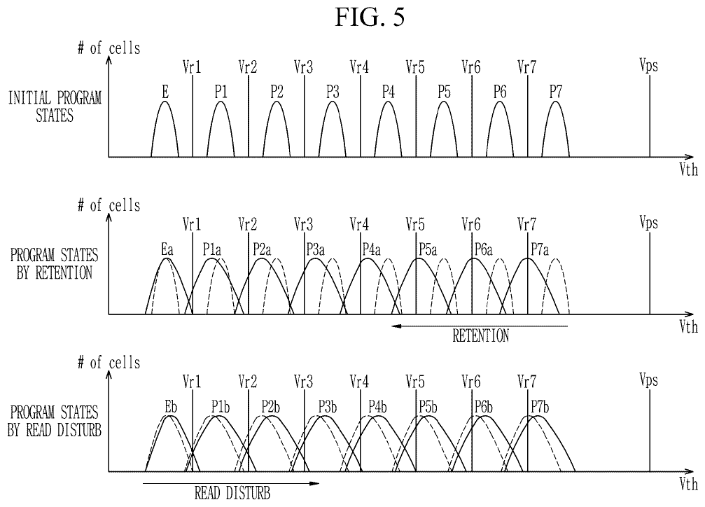

FIG. 5 is a diagram showing examples of changes in threshold voltage distribution of the plurality of memory cells according to some implementations. In FIG. 5, the horizontal axis of the graph represents a threshold voltage Vth of memory cells, and the vertical axis of the graph represents the number of memory cells (# of cells).

FIG. 5 illustrates an example where one memory cell is programmed as a triple level cell (TLC) that stores three bits of data. In FIG. 5, the nonvolatile memory device 1100 may perform a program operation to store data in a plurality of memory cells in response to a command from the storage controller 1200. A plurality of memory cells may be programmed into initial program states (INITIAL PROGRAM STATES) by program operations. The threshold voltage of each of the plurality of memory cells may rise to a threshold voltage corresponding to one of an erased state E and first to seventh program states P1 to P7 while performing the program operation.

The nonvolatile memory device 1100 may perform a read operation that reads data stored in a plurality of memory cells using a plurality of default read voltages. A plurality of default read voltages may include first to seventh default read voltages Vr1 to Vr7. Each of the first to seventh default read voltages Vr1 to Vr7 may be a voltage that identifies the threshold voltage of the memory cells corresponding to the erase state E and the first to seventh program states P1 to P7, respectively. In some implementations, the nonvolatile memory device 1100 may read data stored in memory cells having a threshold voltage corresponding to the seventh program state P7 among the plurality of memory cells using the seventh default read voltage Vr7.

The threshold voltage of the plurality of memory cells programmed with the initial program states INITIAL PROGRAM STATES may change depending on the retention phenomenon. The retention phenomenon may be a phenomenon in which a threshold voltage of a plurality of memory cells decreases over time. The threshold voltage of the plurality of memory cells may change corresponding to one of an erase state Ea and a state of one of the first to seventh program states P1a to P7a depending on the retention phenomenon.

The threshold voltage of the plurality of memory cells, which has changed according to the retention phenomenon, may change again according to a read disturb phenomenon. The read disturb phenomenon may be a phenomenon in which a threshold voltage of unselected memory cells increases as a default read pass voltage greater than the default read voltage is applied to unselected word lines connected to the unselected memory cells among the plurality of memory cells while the default read voltage is applied to selected word lines connected to selected memory cells among the plurality of memory cells. The threshold voltage of the plurality of memory cells may change corresponding to one of an erase state Eb and a state of one of the first to seventh program states P1b to P7b depending on the read disturb phenomenon.

The read disturb phenomenon may also occur in a structure of a memory block that includes a plurality of sub-blocks. In some implementations, while reading data stored in selected memory cells connected to selected word lines of a selected sub-block among a plurality of sub-blocks, a threshold voltage of memory cells connected to unselected word lines of the selected sub-block and a threshold voltage of memory cells connected to unselected word lines of unselected sub-blocks among the plurality of sub-blocks may change depending on the read disturb phenomenon.

When the threshold voltage of the plurality of memory cells changes due to the retention phenomenon and the read disturb phenomenon, data read from the plurality of memory cells using a default read voltage may include error bits, and an error correction operation for data including error bits may fail.

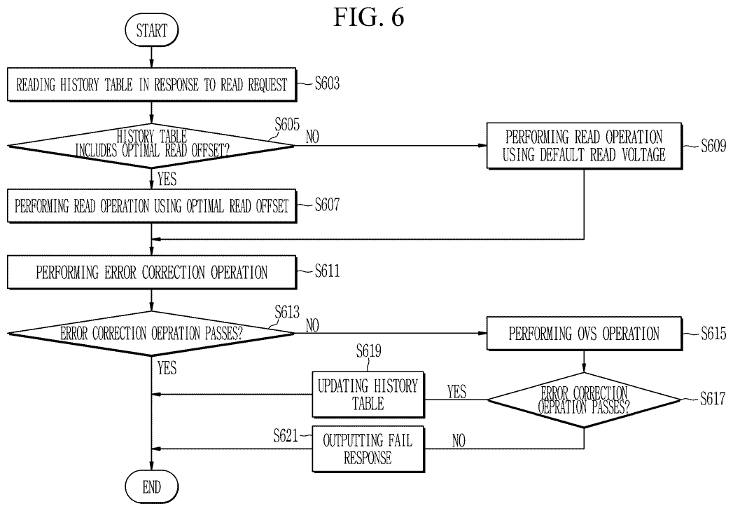

FIG. 6 is a diagram showing an example of a storage device performing a read operation according to some implementations. In FIG. 6, in S603, the storage device 1000 may read the history table 1223 stored in the buffer memory 1220 responding to a read request for requesting data stored in a selected sub-block among a plurality of sub-block.

In S605, the storage device 1000 may identify whether the history table 1223 includes an optimal read offset of the selected sub-block among the plurality of sub-blocks. In some implementations, the history table 1223 may not contain the optimal read offset of the selected sub-block when error correction has never failed on data read from the selected sub-block using the default read voltage. In some implementations, the history table 1223 may include a read offset as an optimal read offset of the selected sub-block when an error correction operation on data read from the selected sub-block using the default read voltage has failed and an error correction operation on data read from the selected sub-block using a read offset having a predetermined difference from the default read voltage has passed.

In S607, the storage device 1000 may perform a read operation using the optimal read offset when the history table 1223 includes the optimal read offset of the selected sub-block. In some implementations, the storage controller 1200 may provide a read command that reads data stored in the selected sub-block in response to a read request and an optimal read offset of the selected sub-block identified based on the history table 1223 to the nonvolatile memory device 1100. The nonvolatile memory device 1100 may, in response to a read command, apply a read voltage corresponding to a difference between the default read voltage and the optimal read offset to a selected word line of the selected sub-block.

In S609, the storage device 1000 may perform a read operation using the default read voltage when the history table 1223 does not contain the optimal read offset of the selected sub-block. In some implementations, the storage controller 1200 may provide a read command to the nonvolatile memory device 1100, and the nonvolatile memory device 1100 may apply a default read voltage to the selected word line of the selected sub-block. The default read voltage may be any one of the first to seventh default read voltages Vr1 to Vr7 in FIG. 5.

In S611, the storage device 1000 may perform an error correction operation on data read from the selected sub-block. The storage device 1000 may correct error bits contained in data read from the selected sub-block while performing the error correction operation.

In S613, the storage device 1000 may identify whether an error correction operation has passed. The error correction operation may fail when the number of error bits contained in the data read from the selected sub-block is greater than the number of uncorrectable bits. When the number of error bits contained in the data read from the selected sub-block is less than the number of non-correctable bits, the error correction operation can be passed. The storage device 1000 may provide error-corrected data to the host 2000 when the error correction operation passes.

In S615, the storage device 1000 may perform an OVS operation when the error correction operation for data read from selected sub-block fails. The storage device 1000 may determine the optimal read offset of the selected sub-block based on the cell count information obtained by the OVS operation, and read data stored in the selected sub-block using the optimal read offset. In some implementations, the nonvolatile memory device 1100 may perform a read operation that applies an optimal read voltage corresponding to the difference between the default read voltage and the optimal read offset to a selected word line of the selected sub-block.

In S617, the storage device 1000 may identify whether the error correction operation for data read from the selected sub-block has passed using the optimal read offset.

In S619, the storage device 1000 may update the history table 1223 when the error correction operation for data read from the selected sub-block passes using optimal read offset. In some implementations, the storage device 1000 may add the optimal read offset of the selected sub-block to the history table 1223.

In S621, the storage device 1000 may output a fail response to the host 2000 indicating that the read request has failed when the error correction operation on the data read from the selected sub-block using the optimal read offset fails.

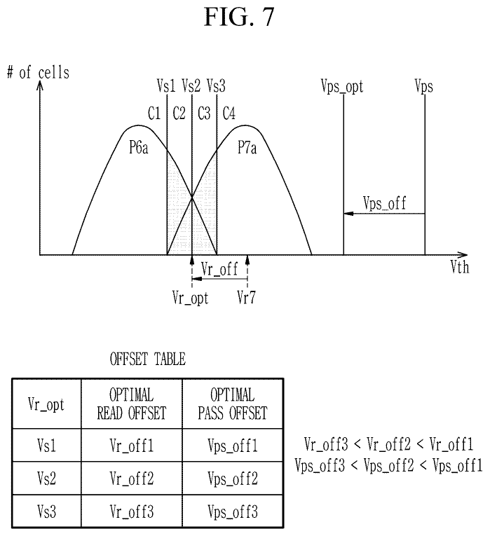

FIG. 7 is a diagram showing an example of a storage device that determines an optimal read offset and an optimal read pass offset based on an optimal read voltage determined by the OVS operation according to some implementations. In FIG. 7, the horizontal axis of the graph represents a threshold voltage Vth of the memory cells, and the vertical axis of the graph represents the number of memory cells (# of cells).

In FIG. 7, the read operation controller 1211 may control the nonvolatile memory device 1100 to perform an OVS operation when an error correction operation for data read from the selected sub-block among the plurality of sub-blocks fails. The nonvolatile memory device 1100 may identify threshold voltages of the plurality of memory cells by using a plurality of search voltages while performing an OVS operation. In some implementations, the plurality of search voltages may include first to third search voltages Vs1 to Vs3.

The nonvolatile memory device 1100 may identify threshold voltages of the plurality of memory cells having threshold voltages corresponding to adjacent program states among a plurality of program states while performing the OVS operation, and generate cell count information corresponding to a result of identifying the threshold voltages of the plurality of memory cells. In some implementations, adjacent program states may be a top-level program state and a program state adjacent to the top-level program state. In some implementations, when the memory cells are programmed with TLC, the top-level program state and the program states adjacent to the top-level program state may be the sixth program state P6a and the seventh program state P7a.

In some implementations, the nonvolatile memory device 1100 may count the number of memory cells having a threshold voltage that is lower or higher than the plurality of search voltages among the plurality of memory cells while performing the OVS operation. For example, the nonvolatile memory device 1100 may count the number of first on cells having a threshold voltage lower than a first search voltage Vs1, the number of second on cells having a threshold voltage lower than a second search voltage Vs2, the number of third on cells having a threshold voltage lower than a third search voltage Vs3, and the number of off cells having a threshold voltage higher than the third search voltage Vs3 among a plurality of memory cells having threshold voltages corresponding to the sixth program state P6a and the seventh program state P7a. The nonvolatile memory device 1100 may provide cell count information to the read level controller 1212, which indicates the number of first on cells, the number of second on cells, the number of third on cells, and the number of off cells.

In some implementations, the read level controller 1212 can determine the number of memory cells having threshold voltages corresponding to the first zone C1, the second zone C2, the third zone C3, and the fourth zone C4, respectively, based on cell count information. For example, the read level controller 1212 may determine the number of first-on cells having a threshold voltage lower than the first search voltage Vs1 as the number of memory cells having a threshold voltage corresponding to the first area C1. For example, the read level controller 1212 may determine the number of memory cells having a threshold voltage corresponding to a second region C2 as a difference between the number of second-on cells having a threshold voltage lower than the second search voltage Vs2 and the number of first-on cells having a threshold voltage lower than the first search voltage Vs1. For example, the read level controller 1212 may determine the number of memory cells having a threshold voltage corresponding to a third region C3 as a difference between the number of third-on cells having a threshold voltage lower than the third search voltage Vs3 and the number of second-on cells having a threshold voltage lower than the second search voltage Vs2. For example, the read level controller 1212 may determine the number of off cells having a threshold voltage higher than the third search voltage Vs3 as the number of memory cells having a threshold voltage corresponding to a fourth zone C4.

The read level controller 1212 may determine an optimal read voltage Vr_opt corresponding to a valley of adjacent program states based on the number of memory cells having threshold voltages corresponding to the first zone C1, the second zone C2, the third zone C3, and the fourth zone C4, respectively.

The read level controller 1212 may determine an optimal read offset Vr_off and an optimal read pass offset Vps_off corresponding to the magnitude of the optimal read voltage Vr_opt based on the offset table 1222. For example, the optimal read offset Vr_off may correspond to the magnitude difference between the seventh default read voltage Vr7 and the optimal read voltage Vr_opt. The optimal read pass offset Vps_off may correspond to the magnitude difference between the default read pass voltage Vps and the optimal read pass voltage Vps_opt.

The read level controller 1212 may determine the second search voltage Vs2 corresponding to a valley of the sixth program state P6a and the seventh program state P7a as the optimal read voltage Vr_opt based on the number of memory cells in each of the first zone C1, the second zone C2, the third zone C3, and the fourth zone C4, as shown in FIG. 7. The read level controller 1212 may determine a second optimal read offset Vr_off2 and a second optimal read pass offset Vps_off2 corresponding to the second search voltage Vs2 determined by the optimal read voltage Vr_opt based on the offset table 1222 as the optimal read offset Vr_off and the optimal read pass offset Vps_off.

The read level controller 1212 may determine a first optimal read offset Vr_off1 and a first optimal read pass offset Vps_off1 corresponding to the first search voltage Vs1 based on the offset table 1222 as the optimal read offset Vr_off and the optimal read pass offset Vps_off, when the optimal read voltage Vr_opt corresponding to the valley of the sixth program state P6a and the seventh program state P7a is determined as the first search voltage Vs1.

The read level controller 1212 may determine a third optimal read offset Vr_off3 and a third optimal read pass offset Vps_off3 corresponding to the third search voltage Vs3 based on the offset table 1222 as the optimal read offset Vr_off and the optimal read pass offset Vps_off, when the optimal read voltage Vr_opt corresponding to the valley of the sixth program state P6a and the seventh program state P7a is determined as the third search voltage Vs3.

In some implementations, the magnitude of the first search voltage Vs1 may be smaller than the second search voltage Vs2. The second search voltage Vs2 may be smaller than the third search voltage Vs3.

The magnitude of the first optimal read offset Vr_off1 may be larger than the second optimal read offset Vr_off2. The magnitude of the second optimal read offset Vr_off2 may be larger than the third optimal read offset Vr_off3.

The magnitude of a first optimal read pass offset Vps_off1 may be larger than a second optimal read pass offset Vps_off2. The magnitude of the second optimal read pass offset Vps_off2 may be larger than a third optimal read pass offset Vps_off3.

Here, the optimal read offset and optimal read pass offset corresponding to the optimal read voltage may be decreased as the magnitude of the optimal read voltage determined based on the cell count information acquired by the OVS operation is increased.

The read level controller 1212 may determine the optimal read offset Vr_off as the first optimal read offset Vr_off1 when the optimal read voltage Vr_opt is determined as the first search voltage Vs1, and may determine the optimal read offset Vr_off as the second optimal read offset Vr_off2 that is smaller than the first optimal read offset Vr_off1 when the optimal read voltage Vr_opt is determined as the first search voltage Vs1. In some implementations, the read level controller 1212 may determine the optimal read offset Vr_off as the second optimal read offset Vr_off2 when the optimal read voltage Vr_opt is determined as the second search voltage Vs2, and may determine the optimal read offset Vr_off a the third optimal read offset Vr_off3 that is smaller than the second optimal read offset Vr_off2 when the optimal read voltage Vr_opt is determined as the third search voltage Vs3 that is larger than the second search voltage Vs2.

The read level controller 1212 may determine the optimal read pass offset Vps_off as the third optimal read pass offset Vps_off3 when the optimal read voltage Vr_opt is determined as the third search voltage Vs3, and may determine the optimal read pass offset Vps_off as the second optimal read pass offset (Vps_off2 that is greater than the third optimal read pass offset Vps_off3 when the optimal read voltage Vr_opt is determined as the second search voltage Vs2 that is less than the third search voltage Vs3. In some implementations, the read level controller 1212 may determine the optimal read pass offset Vps_off as the second optimal read pass offset (Vps_off2) when the optimal read voltage Vr_opt is determined as the second search voltage Vs2, and may determine the optimal read pass offset Vps_off as the first optimal read pass offset Vps_off1 that is greater than the second optimal read pass offset Vps_off2 when the optimal read voltage Vr_opt is determined as the first search voltage Vs1 that is smaller than the second search voltage Vs2.

The read level controller 1212 may determine the optimal read voltage Vr_opt based on cell count information acquired by the OVS operation, determine the optimal read offset Vr_off and the optimal read pass offset Vps_off corresponding to the magnitude of the optimal read voltage Vr_opt based on the magnitude of the optimal read voltage Vr_opt, and update the optimal read offset Vr_off and the optimal read pass offset Vps_off in the history table 1223. In some implementations, the read operation controller 1211 may provide the optimal read offset Vr_off and the optimal read pass offset Vps_off to the nonvolatile memory device 1100 based on the history table 1223 during the read operation.

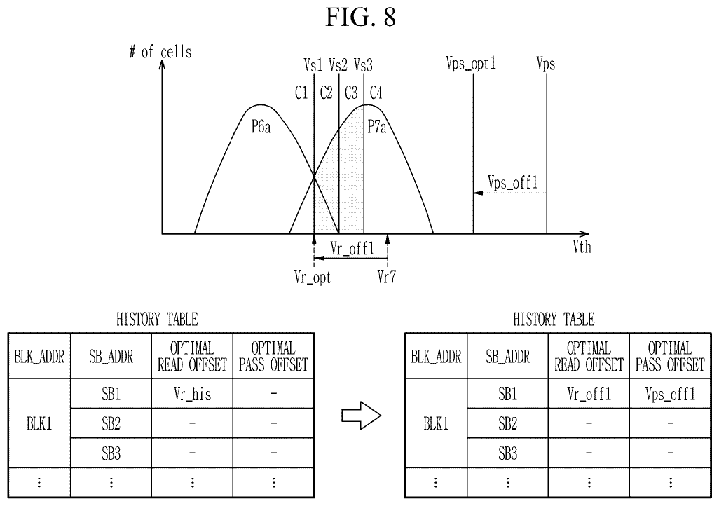

FIG. 8 is a diagram showing an example of a storage device that updates the magnitude of an optimal read voltage according to some implementations. In FIG. 8, the horizontal axis of the graph represents the threshold voltage Vth of the memory cells, and the vertical axis of the graph represents the number of memory cells (# of cells).

In FIG. 8, the read level controller 1212 may obtain cell count information corresponding to a result of the OVC operation performed on the selected sub-block from the nonvolatile memory device 1100, and may determine the number of memory cells having threshold voltages respectively corresponding to the first zone C1, the second zone C2, the third zone C3, and the fourth zone C4 based on the cell count information.

The read level controller 1212 may identify the second zone C2 and the third zone C3 having a number of memory cells less than a predetermined number based on the number of memory cells having threshold voltages corresponding to the first zone C1, the second zone C2, the third zone C3, and the fourth zone C4, respectively. In some implementations, the read level controller 1212 may determine the optimal read voltage Vr_opt corresponding to the valleys of the sixth program state P6a and the seventh program state P7a based on the number of memory cells in the second zone C2 and the number of memory cells in the third zone C3. In some implementations, the read level controller 1212 may determine the first search voltage Vs1 as the optimal read voltage Vr_opt when the number of memory cells in the third zone C3 is greater than the number of memory cells in the second zone C2 and a difference between the number of memory cells in the third zone C3 and the number of memory cells in the second zone C2 is greater than the number of reference cells.

In some implementations, the read level controller 1212 may determine the optimal read offset and the optimal read pass offset corresponding to the optimal read voltage Vr_opt based on the magnitude of the first search voltage Vs1 determined by the optimal read voltage Vr_opt. For example, the read level controller 1212 may determine the first optimal read offset Vr_off1 and the first optimal read pass offset Vps_off1 corresponding to the first search voltage Vs1 as the optimal read offset and the optimal read pass offset based on the offset table 1222. For example, the first optimal read offset Vr_off1 may correspond to a magnitude difference between the seventh default read voltage Vr7 and the first search voltage Vs1. For example, the first optimal read pass offset Vps_off1 may correspond to a magnitude difference between the default read pass voltage Vps and the first optimal read pass voltage Vps_opt1.

In some implementations, the read level controller 1212 may update the history table 1223 with the first optimal read offset Vr_off1 and the first optimal read pass offset Vps_off1 as the optimal read offset and optimal read pass offset of the selected sub-block that performed the OVS operation. For example, when the selected sub-block that performed the OVS operation is the first sub-block SB1, the optimal read offset of the first sub-block SB1 in the history table 1223 may be updated from a history offset Vr_his to the first optimal read offset Vr_off1, and the optimal read pass offset of the first sub-block SB1 may be added to the first optimal read pass offset Vps_off1.

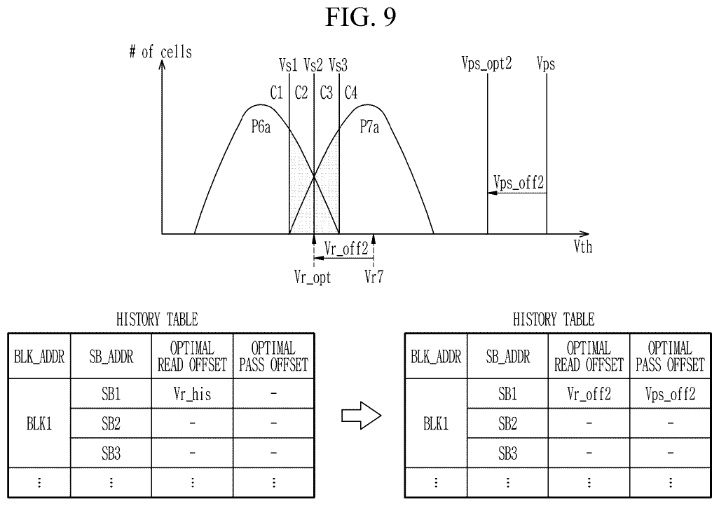

FIG. 9 is a diagram showing an example of a storage device that updates a history table based on the magnitude of an optimal read voltage according to some implementations. In FIG. 9, the horizontal axis of the graph represents a threshold voltage Vth of memory cells, and the vertical axis of the graph represents the number of memory cells (# of cells).

In FIG. 9, a read level controller 1212 obtains cell count information corresponding to a result of performing an OVS operation on a selected sub-block from a nonvolatile memory device 1100, and determines the number of memory cells having threshold voltages corresponding to a first zone C1, a second zone C2, a third zone C3, and a fourth zone C4, respectively, based on the cell count information.

The read level controller 1212 may determine an optimal read voltage Vr_opt corresponding to valleys of a sixth program state P6a and a seventh program state P7a based on the number of memory cells in the second zone C2 and the number of memory cells in the third zone C3.

The read level controller 1212 may determine a second search voltage Vs2 as an optimal read voltage Vr_opt when a difference between the number of memory cells in the second zone C2 and the number of memory cells in the third zone C3 is less than the number of reference cells.

The read level controller 1212 may determine an optimal read offset and an optimal read pass offset corresponding to the optimal read voltage Vr_opt based on the magnitude of the second search voltage Vs2 determined by the optimal read voltage Vr_opt. For example, the read level controller 1212 may determine a second optimal read offset Vr_off2 and a second optimal read pass offset Vps_off2 corresponding to the second search voltage Vs2 as the optimal read offset and the optimal read pass offset based on an offset table 1222. For example, the second optimal read offset Vr_off2 may correspond to a magnitude difference between a seventh default read voltage Vr7 and the second search voltage Vs2. For example, the second optimal read pass offset Vps_off2 may correspond to the magnitude difference between a default read pass voltage Vps and a second optimal read pass voltage Vps_opt2.

When a selected sub-block that performed an OVS operation is a first sub-block SB1, the read level controller 1212 may update an optimal read offset of the first sub-block SB1 from a history offset Vr_his to the second optimal read offset Vr_off2 in the history table 1223, and add the optimal read pass offset of the first sub-block SB1 to the second optimal read pass offset Vps_off2.

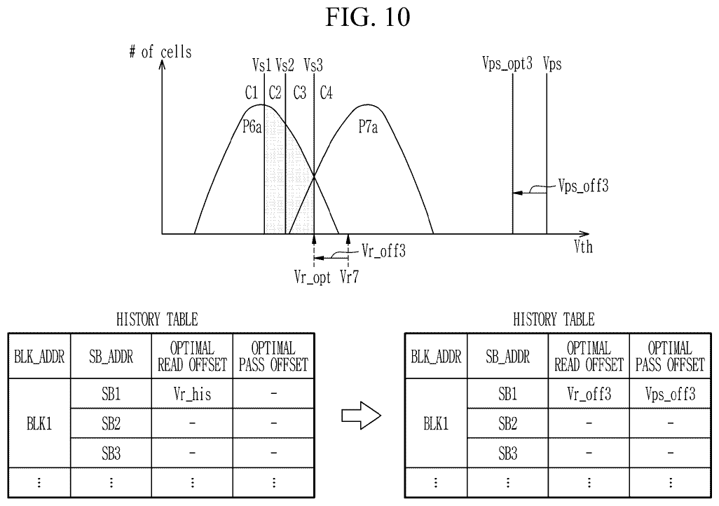

FIG. 10 is a diagram showing an example of a storage device that updates a history table based on the magnitude of an optimal read voltage according to some implementations. In FIG. 10, the horizontal axis of the graph represents a threshold voltage Vth of memory cells, and the vertical axis of the graph represents the number of memory cells (# of cells).

In FIG. 10, the read level controller 1212 may determine an optimal read voltage Vr_opt corresponding to a valley of a sixth program state P6a and a seventh program state P7a based on the number of memory cells in a second zone C2 and the number of memory cells in a third zone C3. In some implementations, the read level controller 1212 may determine a third search voltage Vs3 as the optimal read voltage Vr_opt when the number of memory cells in the second zone C2 is greater than the number of memory cells in the third zone C3, and a difference between the number of memory cells in the second zone C2 and the number of memory cells in the third zone C3 is greater than the number of reference cells.

In some implementations, the read level controller 1212 may determine an optimal read offset and an optimal read pass offset corresponding to the optimal read voltage Vr_opt based on the magnitude of the third search voltage Vs3 determined by the optimal read voltage Vr_opt. For example, the read level controller 1212 may determine a third optimal read offset Vr_off3 and a third optimal read pass offset Vps_off3 corresponding to the third search voltage Vs3 as the optimal read offset and the optimal read pass offset based on the offset table 1222. For example, the third optimal read offset Vr_off3 may correspond to a magnitude difference between a seventh default read voltage Vr7 and the third search voltage Vs3. For example, the third optimal read pass offset Vps_off3 may correspond to the magnitude difference between a default read pass voltage Vps and the third optimal read pass voltage Vps_opt3.

When a selected sub-block that performed an OVS operation is a first sub-block SB1, the read level controller 1212 may update the optimal read offset of the first sub-block SB1 in the history table 1223 from a history offset Vr_his to a third optimal read offset Vr_off3, and add the optimal read pass offset of the first sub-block SB1 to the third optimal read pass offset Vps_off3.

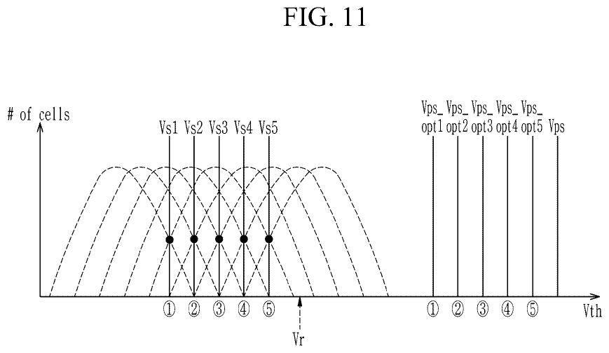

FIG. 11 is a diagram showing an example of an optimal read pass voltage determined based on the magnitude of an optimal read voltage according to some implementations. In FIG. 11, the horizontal axis of the graph represents a threshold voltage Vth of memory cells, and the vertical axis of the graph represents the number of memory cells (# of cells).

In FIG. 11, the nonvolatile memory device 1100 may perform an OVS operation on a selected sub-block among a plurality of sub-blocks using a plurality of search voltages. In some implementations, the plurality of search voltages may include first to fifth search voltages Vs1 to Vs5. In some implementations, the nonvolatile memory device 1100 may provide cell count information corresponding to a result of performing the OVS operation to the read level controller 1212.

The read level controller 1212 may determine an optimal read voltage corresponding to a valley of adjacent program states among a plurality of program states based on the cell count information.

The read level controller 1212 may determine the first search voltage Vs1 as the optimal read voltage based on the cell count information, and determine the first optimal read pass offset corresponding to the first search voltage Vs1 based on the magnitude of the first search voltage Vs1. A nonvolatile memory device may apply a first optimal read pass voltage Vps_opt1 corresponding to a difference between the default read pass voltage Vps and the first optimal read pass offset to unselected word lines of the selected sub-block and unselected sub-blocks based on the first optimal read pass offset while performing a read operation for the selected sub-block.

The read level controller 1212 may determine a second search voltage Vs2, which is greater than the first search voltage Vs1, as the optimal read voltage based on the cell count information, and may determine a second optimal read pass offset corresponding to the second search voltage Vs2 based on the magnitude of the second search voltage Vs2. The nonvolatile memory device 1100 may apply a second optimal read pass voltage Vps_opt2 corresponding to the difference between the default read pass voltage Vps and the second optimal read pass offset to the unselected word lines of the selected sub-block and unselected sub-blocks based on the second optimal read pass offset while performing a read operation for the selected sub-block. In some implementations, the second optimal read pass voltage Vps_opt2 can be greater than the first optimal read pass voltage Vps_opt1.

In some implementations, the optimal read pass voltage may be increased as the magnitude of the optimal read voltage is increased. For example, when a third search voltage Vs3, which is greater than the second search voltage Vs2, is determined as the optimal read voltage, a third optimal read pass voltage Vps_opt3, which is greater than the second optimal read pass voltage Vps_opt2, may be applied to unselected word lines of the selected sub-block and unselected sub-blocks. For example, when a fourth search voltage Vs4, which is greater than the third search voltage Vs3, is determined as the optimal read voltage, a fourth optimal read pass voltage Vps_opt4, which is greater than the third optimal read pass voltage Vps_opt3, may be applied to the unselected word lines of the selected sub-block and unselected sub-blocks. For example, when a fifth search voltage Vs5, which is greater than the fourth search voltage Vs4, is determined as the optimal read voltage, a fifth optimal read pass voltage Vps_opt5, which is greater than the fourth optimal read pass voltage Vps_opt4, may be applied to the unselected word lines of the selected sub-block and unselected sub-blocks.

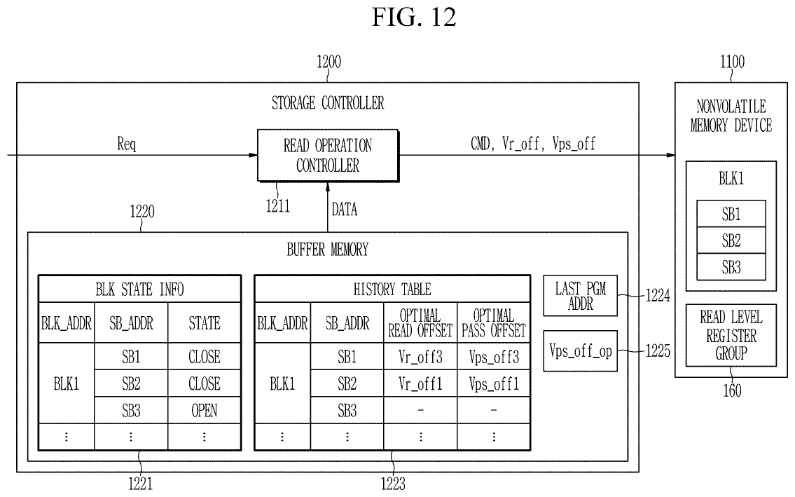

FIG. 12 is a diagram showing an example of a storage controller that provides an optimal read offset and an optimal read pass offset of a sub-block to a nonvolatile memory device in response to a read request according to some implementations. In FIG. 12, the buffer memory 1220 may store a block state information 1221, a history table 1223, a last program address 1224, and an open read pass offset 1225.

The read operation controller 1211 may receive a read request Req for the second sub-block SB2 among the first to third sub-blocks SB1 to SB3 included in the first memory block BLK1 from the host 2000. The read operation controller 1211 may read block state information 1221 stored in the buffer memory 1220 in response to the read request Req. The read operation controller 1211 may identify states of the first sub-block SB1, the second sub-block SB2, and the third sub-block SB3 included in the first memory block BLK1 based on the block state information 1221. In some implementations, the read operation controller 1211 may identify that the first sub-block SB1 and the second sub-block SB2 correspond to a closed block CLOSE, and the third sub-block SB3 corresponds to an open block OPEN based on the block state information 1221.

The read operation controller 1211 may read the history table 1223 in response to the read request Req. The read operation controller 1211 may identify the third optimal read pass offset Vps_off3 of the first sub-block SB1 and the first optimal read pass offset Vr_off1 and the first optimal read pass offset Vps_off1 of the second sub-block SB2 based on the history table 1223.

The third optimal read pass offset Vps_off3 of the first sub-block SB1 may be an optimal read pass offset corresponding to the magnitude of the optimal read voltage determined based on the first cell count information obtained by the OVS operation for the first sub-block SB1.

The first optimal read offset Vr_off1 and the first optimal read pass offset Vps_off1 of the second sub-block SB2 may be the optimal read offset and the optimal read pass offset corresponding to the magnitude of the optimal read voltage determined based on the second cell count information obtained by the OVS operation for the second sub-block SB2.

The read operation controller 1211 may identify the third sub-block SB3 corresponding to the open block OPEN based on the block state information 1221, and read the last program address 1224 and the open read pass offset 1225 of the third sub-block SB3. The read operation controller 1211 may provide a read command CMD for reading data stored in the second sub-block SB2 in response to the read request Req, a third optimal read pass offset Vps_off3 of the first sub-block SB1, the first optimal read offset Vr_off1 and the first optimal read pass offset Vps_off1 of the second sub-block SB2, the last program address 1224 of the third sub-block SB3, and the open read pass offset 1225 to the nonvolatile memory device 1100.

The nonvolatile memory device 1100 may store the third optimal read pass offset Vps_off3 of the first sub-block SB1, the first optimal read offset Vr_off1 and the first optimal read pass offset Vps_off1 of the second sub-block SB2, and the open read pass offset 1225 in the read level register group 160. The nonvolatile memory device 1100 may, in response to the read command CMD, apply an optimal read pass voltage to word lines of the first sub-block SB1 based on the third optimal read pass offset Vps_off3, apply an optimal read voltage and an optimal read pass voltage to word lines of the second sub-block SB2 based on the first optimal read offset Vr_off1 and the first optimal read pass offset Vps_off1, and apply an open read pass voltage to open word lines among word lines of the third sub-block SB3 based on the last program address 1224 and the open read pass offset 1225.

When the read operation controller 1211 receives the read request Req for the first sub-block SB1 among the first to third sub-blocks SB1 to SB3 included in the first memory block BLK1 from the host 2000, the read operation controller 1211 may identify the third sub-block SB3 corresponding to the open block OPEN among the first to third sub-blocks SB1 to SB3 based on block state information 1221, identify the third optimal read offset Vr_off3 and the third optimal read pass offset Vps_off3 of the first sub-block SB1 based on the history table 1223, and identify the first optimal read pass offset Vps_off1 of the second sub-block SB2.

The read operation controller 1211 may respond to the read request Req for the first sub-block SB1 by providing the read command CMD for reading data stored in the first sub-block SB1, the third optimal read offset Vr_off3 and the third optimal read pass offset Vps_off3 of the first sub-block SB1, the first optimal read pass offset Vps_off1, an open read pass offset Vps_off_op of the second sub-block SB2, and the last program address 1224 of the third sub-block SB3 to the nonvolatile memory device 1100.

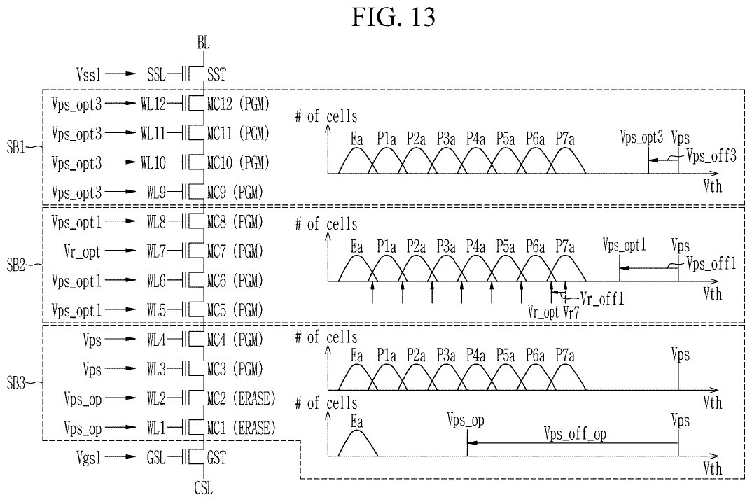

FIG. 13 is a diagram showing an example of a nonvolatile memory device applying an optimal read voltage and an optimal read pass voltage to a plurality of sub-blocks according to some implementations. In FIG. 13, the horizontal axis of the graph represents a threshold voltage Vth of memory cells, and the vertical axis of the graph represents the number of memory cells (# of cells).

In FIG. 13, the memory cell string NS included in the first memory block BLK1 may be connected between the bit line BL and the common source line CSL. The memory cell string NS may include a string selection transistor SST, a plurality of memory cells MC1 to MC12, and a ground selection transistor GST. The string selection transistor SST may be connected to the string selection line SSL. A plurality of memory cells MC1 to MC12 may be connected to the plurality of word lines WL1 to WL12, respectively. The ground selection transistor GST may be connected to a ground selection line GSL.

The first memory block BLK1 may include a first sub-block SB1, a second sub-block SB2, and a third sub-block SB3. The first sub-block SB1 may include ninth to twelfth memory cells MC9 to MC12. The first sub-block SB1 may be connected to the ninth to twelfth word lines WL9 to WL12, which are connected to the ninth to twelfth memory cells MC9 to MC12. The second sub-block SB2 may include fifth to eighth memory cells MC5 to MC8. The second sub-block SB2 may be connected to the fifth to eighth word lines WL5 to WL8, which are connected to the fifth to eighth memory cells MC5 to MC8. The third sub-block SB3 may include first to fourth memory cells MC1 to MC4. The third sub-block SB3 may be connected to the first to fourth word lines WL1 to WL4, which are connected to the first to fourth memory cells MC1 to MC4.

The third to twelfth memory cells MC3 to MC12 may be programmed memory cells PGM. The programmed memory cells PGM may be memory cells having a threshold voltage corresponding to one of the erase state Ea and the first to seventh program states P1a to P7a depending on the program operation. In some implementations, the first to second memory cells MC1 to MC2 may be memory cells in an erase state ERASE. Memory cells in the erase state ERASE may be memory cells on which no program operations have been performed.

In FIG. 13, the case of reading data stored in the second sub-block SB2 among the first to third sub-blocks SB1 to SB3 will be described. The nonvolatile memory device 1100 may receive a read command to read data stored in the second sub-block SB2 selected from among the first to third sub-blocks SB1 to SB3, a third optimal read pass offset Vps_off3 of the first sub-block SB1, a first optimal read offset Vr_off1 and a first optimal read pass offset Vps_off1 of the second sub-block SB2, a last program address 1224 of the third sub-block SB3, and an open read pass offset 1225 from the storage controller 1200.

The nonvolatile memory device 1100 may apply an optimal read voltage Vr_opt corresponding to a difference between the default read voltage and the first optimal read offset Vr_off1 to the seventh word line WL7 corresponding to a selected word line among word lines of the second sub-block SB2 in response to the read command. In some implementations, the optimal read voltage Vr_opt may be a voltage corresponding to a difference between the seventh default read voltage Vr7 and the first optimal read offset Vr_off1.

The nonvolatile memory device 1100 may apply a first optimal read pass voltage Vps_opt1 corresponding to a difference between a default read pass voltage Vps and a first optimal read pass offset Vps_off1 to the fifth word line WL5, the sixth word line WL6, and the eighth word line WL8 corresponding to unselected word lines among word lines of second sub-block SB2 in response to the read command.

The nonvolatile memory device 1100 may apply the default read pass voltage Vps and a third optimal read pass voltage Vps_opt3 corresponding to a third optimal read pass offset Vps_off3 to the ninth to twelfth word lines WL9 to WL12 corresponding to unselected word lines of the first sub-block SB1 in response to the read command.

The nonvolatile memory device 1100 may, in response to the read command, apply an open read pass voltage Vps_op corresponding to a difference between the default read pass voltage Vps and an open read pass offset Vps_off_op to the first to second word lines WL1 to WL2 corresponding to open word lines among unselected word lines of the third sub-block SB3 based on the last program address 1224. In the embodiment, the last program address 1224 may be an address corresponding to the third word line WL3.

The magnitude of the open read pass offset Vps_off_op may be greater than the first optimal read pass offset Vps_off1. In some implementations, the magnitude of the open read pass voltage Vps_op may be smaller than the first optimal read pass voltage Vps_opt1.

The nonvolatile memory device 1100 may, in response to the read command, apply the default read pass voltage Vps to the third to fourth word lines WL3 to WL4 corresponding to programmed word lines among the unselected word lines of the third sub-block SB3 based on the last program address 1224.

The nonvolatile memory device 1100 may reduce a read disturb phenomenon in which a threshold voltage of programmed memory cells changes due to the default read pass voltage Vps by applying an optimal read pass voltage lower than the default read pass voltage Vps to unselected word lines of a sub-block based on an optimal read pass offset determined by an OVS operation.

The nonvolatile memory device 1100 may reduce a read disturb phenomenon in which a threshold voltage of memory cells in an erase state changes due to the default read pass voltage Vps by applying an open read pass voltage Vps_op smaller than the default read pass voltage Vps to open word lines of an open block based on the last program address 1224 received from the storage controller 1200.

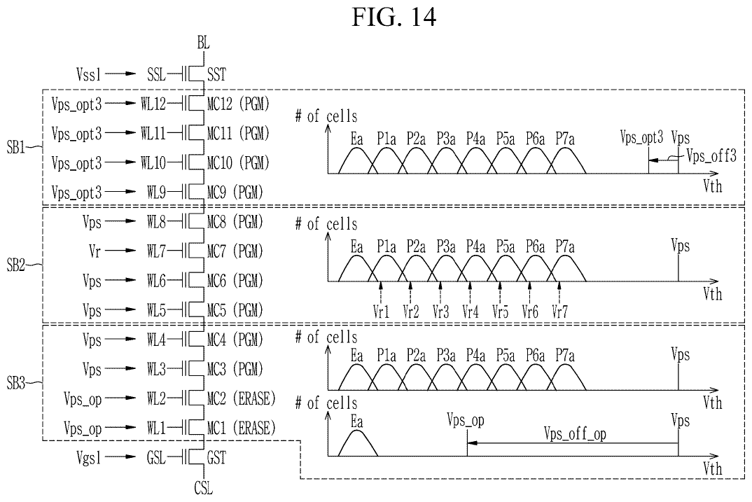

FIG. 14 is a diagram showing an example of a nonvolatile memory device that applies a default read voltage and an optimal read pass voltage to a plurality of sub-block according to some implementations. In FIG. 14, the horizontal axis of the graph represents a threshold voltage Vth of memory cells, and the vertical axis of the graph represents the number of memory cells (# of cells).

In FIG. 14, duplicate content from FIG. 13 is omitted. When an OVS operation for the second sub-block SB2 is not performed, the history table 1223 may not include an optimal read offset and an optimal read pass offset of the second sub-block SB2. In some implementations, when the history table 1223 does not include the optimal read offset and the optimal read pass offset of the second sub-block SB2, the storage controller 1200 may identify the third optimal read pass offset Vps_off3 of the first sub-block SB1 based on the history table 1223 in response to a read request for the second sub-block SB2, and identify the last program address 1224 of the third sub-block SB3 corresponding to an open block.

The storage controller 1200 may respond to the read request by providing a read command to read data stored in the second sub-block SB2, a third optimal read pass offset Vps_off3 of the first sub-block SB1, a last program address 1224 of the third sub-block SB3, and an open read pass offset Vps_off_op to the nonvolatile memory device 1100.

The nonvolatile memory device 1100 may apply a default read voltage to the seventh word line WL7 corresponding to the selected word line of the second sub-block SB2 in response to the read command, and may apply a default read pass voltage Vps to the fifth word line WL5, the sixth word line WL6, and the eighth word line WL8 corresponding to unselected word lines of the second sub-block. The default read voltage may be one of the first to seventh default read voltages Vr1 to Vr7.

The nonvolatile memory device 1100 may apply a default read pass voltage Vps and a third optimal read pass voltage (Vps_opt3) corresponding to the third optimal read pass offset Vps_off3 to the ninth to twelfth word lines WL9 to WL12 corresponding to unselected word lines of the first sub-block SB1 in response to the read command.

The nonvolatile memory device 1100 may, in response to the read command, apply an open read pass voltage Vps_op corresponding to a difference between a default read pass voltage Vps and an open read pass offset Vps_off_op to the first to second word lines WL1 to WL2 corresponding to open word lines among unselected word lines of the third sub-block SB3 based on the last program address 1224.

The nonvolatile memory device 1100 may, in response to the read command, apply the default read pass voltage Vps to the third to fourth word lines WL3 to WL4 corresponding to programmed word lines among the unselected word lines of the third sub-block SB3 based on the last program address 1224.

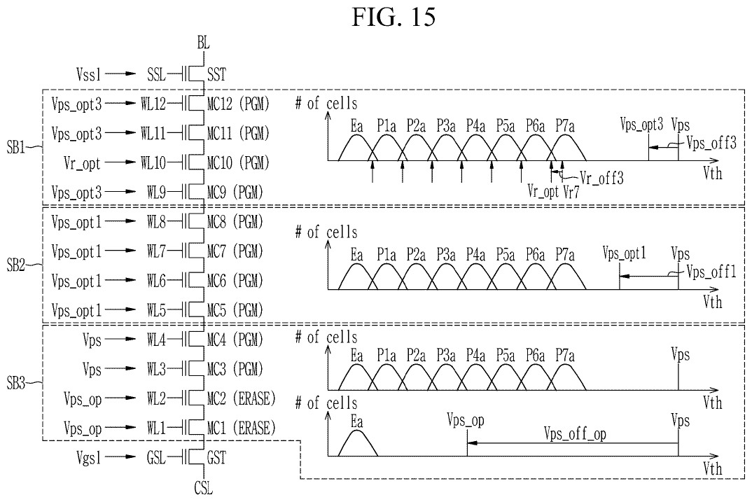

FIG. 15 is a diagram showing an example of a nonvolatile memory device applying an optimal read voltage and an optimal read pass voltage to a plurality of sub-blocks according to some implementations. In FIG. 15, the horizontal axis of the graph represents a threshold voltage Vth of memory cells, and the vertical axis of the graph represents the number of memory cells (# of cells).

In FIG. 15, a case that data stored in a sub-block among the first to third sub-blocks SB1 to SB3 will be described.

The nonvolatile memory device 1100 may receive a read command to read data stored in a selected first sub-block SB1 among the first to third sub-blocks SB1 to SB3, a third optimal read offset Vr_off3 and a third optimal read pass offset Vps_off3 of the first sub-block SB1, a first optimal read pass offset Vps_off1 of the second sub-block SB2 and a last program address 1224 of the third sub-block SB3, and an open read pass offset 1225 from the storage controller 1200.

The nonvolatile memory device 1100 may apply an optimal read voltage Vr_opt corresponding to a difference between a default read voltage and the third optimal read offset Vr_off3 to the tenth word line WL10 corresponding to a selected word line among the word lines of the first sub-block SB1 in response to the read command.

As described with reference to FIG. 7, the third optimal read offset Vr_off3 used to read data stored in the first sub-block SB1 in FIG. 15 may be smaller than the first optimal read offset Vr_off1 used to read data stored in the second sub-block SB2 in FIG. 13. In some implementations, the optimal read voltage Vr_opt corresponding to the difference between the default read voltage applied to the tenth word line WL10 of the first sub-block SB1 and the third optimal read offset Vr_off3 in FIG. 15 may be smaller than the optimal read voltage Vr_opt that corresponds to the difference between the default read voltage applied to the seventh word line WL7 of the first sub-block SB1 and the first optimal read offset Vr_off1 in FIG. 13.

The nonvolatile memory device 1100 may apply a third optimal read pass voltage Vps_opt3 corresponding to a difference between a default read pass voltage Vps and the third optimal read pass offset Vps_off3 to the ninth word line WL9, the eleventh word line WL11, and the twelfth word line WL12 corresponding to unselected word lines among word lines of the first sub-block SB1 in response to the read command.

The third optimal read pass offset Vps_off3 may be smaller than the first optimal read pass offset Vps_off1. In some implementations, the third optimal read pass voltage Vps_opt3 applied to the unselected word lines of the first sub-block SB1 when reading data stored in the first sub-block SB1 in FIG. 15 may be smaller than the first optimal read pass voltage Vps_opt1 applied to the unselected word lines of the second sub-block SB2 when reading data stored in the second sub-block SB2 in FIG. 13.

The nonvolatile memory device 1100 may apply the first optimal read pass voltage Vps_opt1 corresponding to a difference between the default read pass voltage Vps and the first optimal read pass offset Vps_off1 to the fifth to eighth word lines WL5 to WL8 corresponding to unselected word lines of the second sub-block SB2 in response to the read command.

The nonvolatile memory device 1100 may, in response to the read command, apply an open read pass voltage Vps_op corresponding to a difference between the default read pass voltage Vps and an open read pass offset Vps_off_op to the first to second word lines WL1 to WL2 corresponding to open word lines among unselected word lines of the third sub-block SB3 based on the last program address 1224. In some implementations, the last program address 1224 may be an address corresponding to the third word line WL3.

The nonvolatile memory device 1100 may, in response to the read command, apply the default read pass voltage Vps to the third to fourth word lines WL3 to WL4 corresponding to programmed word lines among the unselected word lines of the third sub-block SB3 based on the last program address 1224.

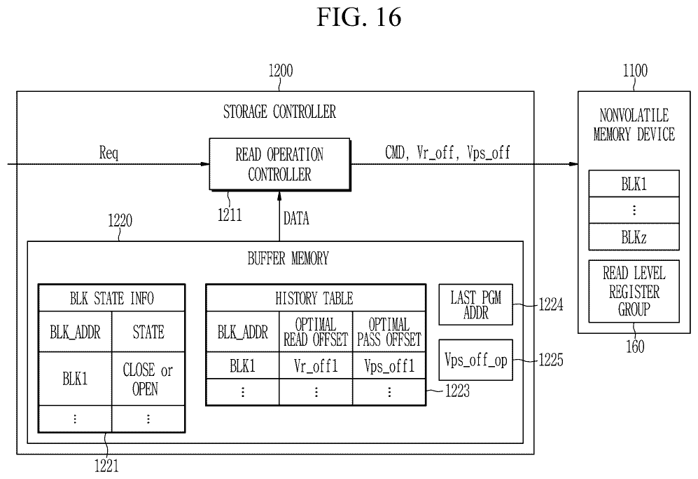

FIG. 16 is a diagram showing an example of a storage controller that provides an optimal read offset and an optimal read pass offset of a memory block to an nonvolatile memory device in respond to a read request according to some implementations. In FIG. 16, the buffer memory 1220 may store the block state information 1221, the history table 1223, the last program address 1224, and the open read pass offset 1225.

The block state information 1221 may include information on a state of each of the plurality of memory blocks BLK1 to BLKz. In some implementations, the block state information 1221 may include information about whether the first memory block BLK1 corresponds to a closed block CLOSE or an open block OPEN.

The history table 1223 may include information about an optimal read offset and an optimal read pass offset of each of the plurality of memory blocks BLK1 to BLKz. The optimal read offset and the optimal read pass offset may be determined based on cell count information obtained by an OVS operation for each of the plurality of memory blocks BLK1 to BLK.

The read operation controller 1211 may receive a read request Req for the first memory block BLK1. The read operation controller 1211 may respond to the read request Req by reading block state information 1221 and may identify a state of the first memory block BLK1.

The read operation controller 1211 may read the history table 1223 when the state of the first memory block BLK1 corresponds to a closed block CLOSE. The read operation controller 1211 may identify the first optimal read offset Vr_off1 and the first optimal read pass offset Vps_off1 of the first memory block BLK1 based on the history table 1223.

The read operation controller 1211 may provide a read command CMD for reading data stored in the first memory block BLK1 in response to the read request Req, the first optimal read offset Vr_off1 of the first memory block BLK1, and the first optimal read pass offset Vps_off1 to the nonvolatile memory device 1100.

The nonvolatile memory device 1100 stores the first optimal read offset Vr_off1 and the first optimal read pass offset Vps_off1 in the read level register group 160, and may read data stored in the first memory block BLK1 based on the first optimal read offset Vr_off1 and the first optimal read pass offset Vps_off1.

The read operation controller 1211 may read the last program address 1224 and the open read path offset 1225 of the first memory block BLK1 when the state of the first memory block BLK1 corresponds to an open block OPEN. The read operation controller 1211 may respond to the read request Req by providing the read command CMD, the last program address 1224, and the open read path offset 1225 to the nonvolatile memory device 1100 to read data stored in the first memory block BLK1.

The nonvolatile memory device 1100 may store the open read path offset in the read level register group, and read data stored in the first memory block BLK1 based on the open read path offset 1225.

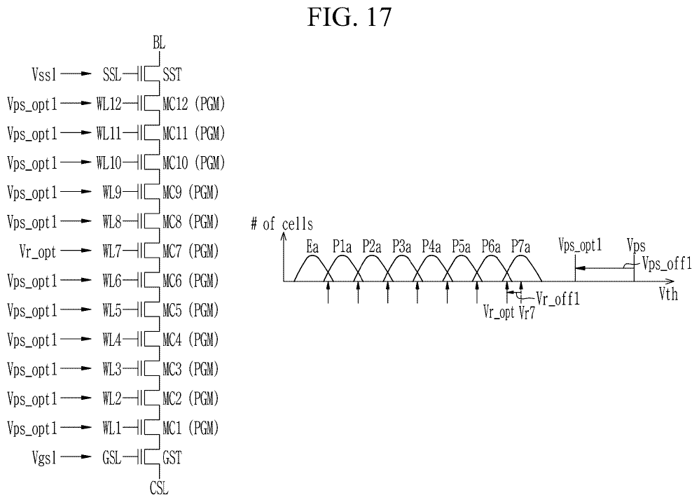

FIG. 17 is a diagram showing an example of a nonvolatile memory device applying an optimal read voltage and an optimal read pass voltage to a memory block according to some implementations. In FIG. 17, the horizontal axis of the graph represents a threshold voltage Vth of memory cells, and the vertical axis of the graph represents the number of memory cells (# of cells).

In FIG. 17, a read operation for the first memory block BLK1 in the case that the first memory block BLK1 corresponds to a closed block will be described. In FIG. 17, when the first memory block BLK1 corresponds to a closed block, the first to twelfth memory cells MC1 to MC12 included in the first memory block BLK1 may be programmed memory cells PGM.

The nonvolatile memory device 1100 may receive the read command for reading data stored in the first memory block BLK1, the first optimal read offset Vr_off1 of the first memory block BLK1, and the first optimal read pass offset Vps_off from the storage controller 1200.

The nonvolatile memory device 1100 may apply an optimal read voltage Vr_opt corresponding to a difference between a default read voltage and the first optimal read offset Vr_off1 to the seventh word line WL7 corresponding to a selected word line among the word lines of the first memory block BLK1 in response to a read command.

The nonvolatile memory device 1100 may apply a first optimal read pass voltage Vps_opt1 corresponding to a difference between a default read pass voltage Vps and the first optimal read pass offset Vps_off1 to first to sixth word lines WL1 to WL6 and eighth to twelfth word lines WL8 to L12 corresponding to unselected word lines among the word lines of the first memory block BLK1 in response to the read command.

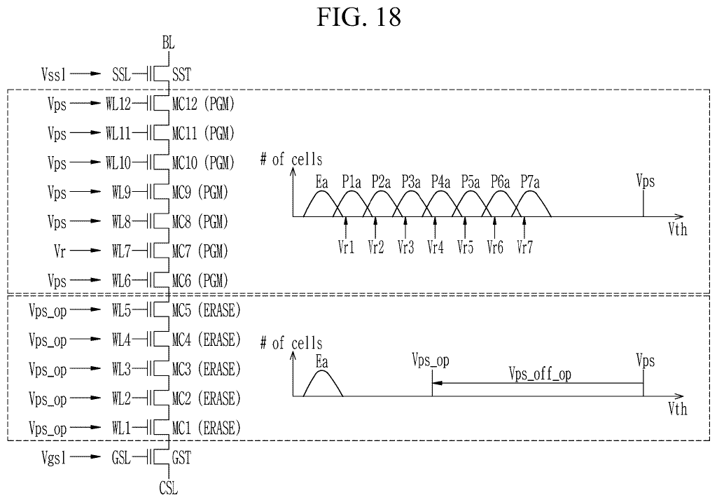

FIG. 18 is a diagram showing an example of a nonvolatile memory device that applies a default read voltage and an open read pass voltage to a memory block according to some implementations. In FIG. 18, the horizontal axis of the graph represents a threshold voltage Vth of memory cells, and the vertical axis of the graph represents the number of memory cells (# of cells).

In FIG. 18, a read operation for the first memory block BLK1 when the first memory block BLK1 corresponds to an open block will be described. In FIG. 18, when the first memory block BLK1 corresponds to an open block, the first to fifth memory cells MC1 to MC5 included in the first memory block BLK1 may be memory cells in the erase state ERASE and the sixth to twelfth memory cells MC6 to MC12 may be programmed memory cells PGM.

The nonvolatile memory device 1100 may receive a read command to read data stored in the first memory block BLK1, a last program address 1224, and an open read pass offset Vps_off_op from the storage controller 1200. In some implementations, the last program address 1224 may be an address corresponding to the sixth word line WL6.

The nonvolatile memory device 1100 may apply a default read voltage to the seventh word line WL7 corresponding to a selected word line among word lines of the first memory block BLK1 in response to a read command.

The nonvolatile memory device 1100 may, in response to the read command, apply an open read pass voltage Vps_op corresponding to a difference between the default read pass voltage Vps and the open read pass offset Vps_off_op to the first to fifth word lines WL1 to WL5 corresponding to open word lines among unselected word lines of the first memory block BLK1 based on the last program address 1224.

The nonvolatile memory device 1100 may, in response to the read command, apply the default read pass voltage Vps to the sixth word line WL6 and the eighth to twelfth word lines WL8 to WL12 corresponding to programmed word lines among the unselected word lines of the first memory block BLK1 based on the last program address 1224.

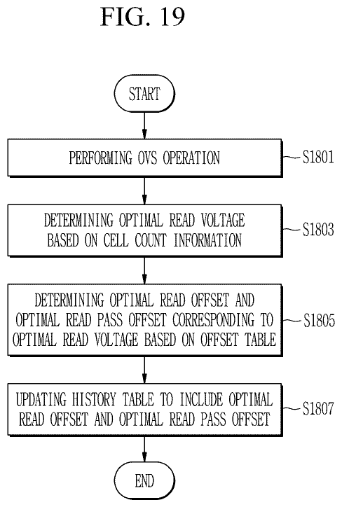

FIG. 19 is a diagram showing an example of a storage controller that updates a history table according to some implementations. In FIG. 19, in S1801, the storage controller 1200 may perform an OVS operation. In some implementations, the storage controller 1200 may perform the OVS operation on a selected sub-block when an error correction operation on data read from the selected sub-block among the plurality of sub-blocks included in the memory block fails.

In S1803, the storage controller 1200 may determine an optimal read voltage based on cell count information. The cell count information may be obtained by the OVS operation for the selected sub-block. In some implementations, the storage controller 1200 may determine a voltage corresponding to a valley of adjacent program states among a plurality of program states as an optimal read voltage based on the cell count information.

In S1805, storage controller 1200 may determine the optimal read offset and the optimal read pass offset of the selected sub-block corresponding to the optimal read voltage based on the offset table. As the magnitude of the optimal read voltage increases, the optimal read offset and optimal read pass offset may be decreased. As the magnitude of the optimal read voltage is decreased, the optimal read offset and optimal read pass offset may be increased.

In S1807, the storage controller 1200 may update the history table to include the optimal read offset and the optimal read pass offset.

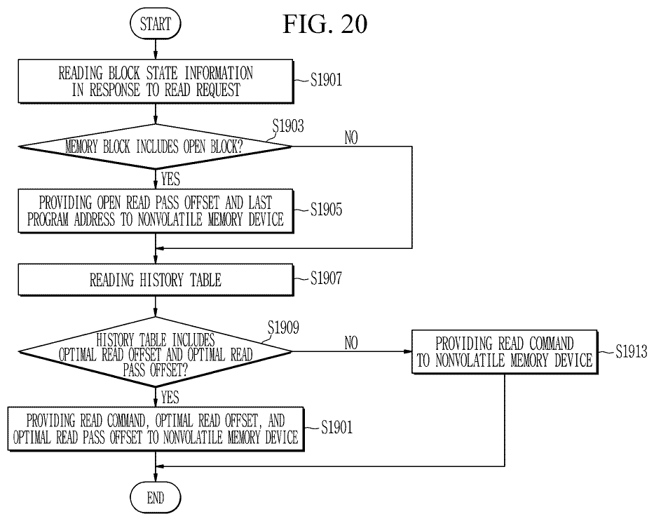

FIG. 20 is a diagram showing an example of a storage controller that provides an optimal read offset and an optimal read pass offset to a nonvolatile memory device based on a history table according to some implementations. In FIG. 20, in S1901, the storage controller 1200 may read block state information in response to a read request. The block state information may include information about whether a plurality of sub-blocks included in a memory block correspond to a closed block or an open block.

In S1903, the storage controller 1200 may identify whether a memory block contains an open block based on the block state information. The step S1905 may be performed when the memory block contains an open block. The step S1907 may be performed when the memory block does not contain an open block.

In S1905, the storage controller 1200 may provide an open read pass offset and a last program address to the nonvolatile memory device 1100 when the memory block contains an open block.

In S1907, the storage controller 1200 may read the history table. The history table may contain information about an optimal read offset and an optimal read pass offset of each of the plurality of sub-blocks included in the memory block.

In S1909, the storage controller 1200 may identify whether the history table contains an optimal read offset and an optimal read pass offset. The step S1913 may be performed when the history table does not contain an optimal read offset and an optimal read pass offset of the plurality of sub-blocks. The step S1911 may be performed when the history table contains the optimal read offset and the optimal read pass offset of the plurality of sub-blocks.

In S1911, the storage controller 1200 may provide a read command, an optimal read offset, and an optimal read pass offset to the nonvolatile memory device 1100. The nonvolatile memory device 1100 may perform a read operation based on the optimal read offset and the optimal read pass offset in response to the read command.

In S1913, the storage controller 1200 may provide the read command to the nonvolatile memory device 1100. The nonvolatile memory device 1100 may perform a read operation based on a default read voltage and a default read pass voltage in response to the read command.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A storage device comprising:
a nonvolatile memory device including a plurality of sub-blocks; and
a storage controller configured to
receive first cell count information from an on chip valley search (OVS) operation for a first sub-block among the plurality of sub-blocks,
generate a first optimal read voltage of the first sub-block based on the first cell count information,
determine a first optimal read pass offset corresponding to the first optimal read voltage based on a magnitude of the first optimal read voltage,
provide a read command and the first optimal read pass offset of the first sub-block to the nonvolatile memory device, and
apply a first optimal read pass voltage that corresponds to a difference between a default read pass voltage and the first optimal read pass offset to word lines of the first sub-block during a period in which the nonvolatile memory device reads data stored in a second sub-block among the plurality of sub-blocks.

2. The storage device of claim 1,
wherein the nonvolatile memory device is configured to apply a default read voltage to a selected word line among word lines of the second sub-block while applying the first optimal read pass voltage to the word lines of the first sub-block, and apply the default read pass voltage to unselected word lines among the word lines of second sub-block, and
wherein the default read pass voltage is greater than the first optimal read pass voltage.

3. The storage device of claim 1, wherein the storage controller is configured to:
receive second cell count information from the OVS operation for a second sub-block among the plurality of sub-blocks,
determine a second optimal read voltage of the second sub-block based on the second cell count information;
determine a first optimal read offset and a second optimal read pass offset based on a magnitude of the second optimal read voltage; and
provide the first optimal read offset and the second optimal read pass offset to the nonvolatile memory device in response to a read request.

4. The storage device of claim 3, wherein the nonvolatile memory device is configured to:
apply the second optimal read voltage corresponding to a difference between a default read voltage and the first optimal read offset to a selected word line among word lines of the second sub-block in response to the read command; and
apply a second optimal read pass voltage corresponding to the default read pass voltage and the second optimal read pass offset to unselected word lines among the word lines of the second sub-block.

5. The storage device of claim 4,
wherein the storage controller is configured to set the magnitude of the first optimal read pass voltage to be greater than the magnitude of the second optimal read pass voltage based on a magnitude of the first optimal read voltage being greater than a magnitude of the second optimal read voltage, and
wherein the storage controller is configured to set the magnitude of the first optimal read pass voltage to be less than the magnitude of the second optimal read pass voltage based on the magnitude of the first optimal read voltage being less than the magnitude of the second optimal read voltage.

6. The storage device of claim 1,
wherein the storage controller is configured to:
set the first optimal read pass offset to be at a first offset level based on the magnitude of the first optimal read voltage corresponding to a first read level; and
set the first optimal read pass offset to be at a second offset level based on the magnitude of the first optimal read voltage corresponding to a second read level,
wherein the second offset level is greater than the first offset level, and
wherein the second read level is less than the first read level.

7. The storage device of claim 1, wherein the storage controller is configured to provide an open read pass offset to the nonvolatile memory device,
wherein the nonvolatile memory device is configured to apply an open read pass voltage to open word lines of a third sub-block among the plurality of sub-blocks during the period in which the non-volatile memory device reads the data stored in the second sub-block, and
wherein the open read pass voltage corresponds to a difference between the default read pass voltage and the open read pass offset.

8. The storage device of claim 7,
wherein the nonvolatile memory device is configured to apply the default read pass voltage to programmed word lines of the third sub-block during the period in which the non-volatile memory device reads the data stored in the second sub-block, and
wherein the default read pass voltage is greater than the open read pass voltage.

9. The storage device of claim 1, wherein the nonvolatile memory device is configured to perform the OVS operation using a plurality of search voltages that identify a threshold voltage of first memory cells having a threshold voltage corresponding to a top-level program state and second memory cells having a threshold voltage corresponding to a program state that is adjacent to the top-level program state among a plurality of memory cells included in the first sub-block.

10. The storage device of claim 9, wherein the nonvolatile memory device is configured to:
count, during performance of the OVS operation, a number of memory cells among the first memory cells and the second memory cells having a threshold voltage that is less than or greater than each search voltage of the plurality of search voltages; and
provide the first cell count information to the storage controller, wherein the first cell count information comprises the number of memory cells that have the threshold voltage less than or greater each search voltage of the plurality of search voltages.

11. A memory device comprising:
a memory cell array including a plurality of sub-blocks;
a voltage generator configured to generate a plurality of voltages to be applied to a plurality of word lines connected to the plurality of sub-blocks; and
a control logic circuit configured to control the voltage generator to
receive a plurality of optimal read offsets and a plurality of optimal read pass offsets,
apply a first optimal read voltage based on a first optimal read offset among the plurality of optimal read offsets and apply a first optimal read pass voltage based on a first optimal read pass offset among the plurality of optimal read pass offsets to a first sub-block among the plurality of sub-blocks in response to a first read command, wherein the first read command comprises a command to read data stored in a first sub-block among the plurality of sub-blocks, and
apply a second optimal read voltage based on a second optimal read offset and a second optimal read pass voltage based on a second optimal read pass offset to a second sub-block among the plurality of sub-blocks in response to a second read command, wherein the second read command comprises a command to read data stored in a second sub-block among the plurality of sub-blocks,
wherein the second optimal read offset is greater than the first optimal read offset, and
wherein the second optimal read pass offset is greater than the first optimal read pass offset.

12. The memory device of claim 11, further comprising a plurality of read level registers configured to store a default read voltage and a default read pass voltage,
wherein the control logic circuit is configured to:
control the voltage generator to apply the first optimal read voltage corresponding to a difference between the default read voltage and the first optimal read offset to a selected word line among word lines of the first sub-block in response to the first read command;
apply the first optimal read pass voltage to unselected word lines among the word lines of the first sub-block, wherein the first optimal read pass voltage corresponds to a difference between the default read pass voltage and the first optimal read pass offset; and
apply the second optimal read pass voltage to unselected word lines among the word lines of the second sub-block, wherein the second optimal read pass voltage corresponds to a difference between the default read pass voltage and the second optimal read pass offset word lines of the second sub-block.

13. The memory device of claim 12, wherein the control logic circuit is configured to control the voltage generator to:
apply a second optimal read voltage to a selected word line among word lines of the second sub-block in response to the second read command, wherein the second optimal rad voltage corresponds to a difference between the default read voltage and the second optimal read offset;
apply the second optimal read pass voltage to unselected word lines among the word lines of the second sub-block, wherein the second optimal read pass voltage corresponds to a difference between the default read pass voltage and the second optimal read pass offset; and
apply the first optimal read pass voltage to word lines of the first sub-block.

14. The memory device of claim 11, wherein the control logic circuit is configured to:
control the voltage generator to receive a last program address and an open read pass offset of a third sub-block corresponding to an open block among the plurality of sub-blocks; and
apply an open read pass voltage to open word lines among word lines of the third sub-block based on the last program address in response to a third read command, wherein the open read pass voltage corresponds to a difference between a default read pass voltage and the open read pass offset.

15. The memory device of claim 14, wherein the control logic circuit is configured to control the voltage generator to apply the default read pass voltage to programmed word lines among the word lines of the third sub-block based on the last program address in response to the third read command.

16. A storage controller comprising:
a buffer memory configured to store a history table including information on an offset of a voltage to be applied to a plurality of sub-blocks included in a nonvolatile memory device;
a read level controller configured to determine a first optimal read voltage of a first sub-block among the plurality of sub-blocks based on a result of performing, by the nonvolatile memory device, an on chip valley search (OVS) operation for the first sub-block, and add a first optimal read offset and a first optimal read pass offset corresponding to a magnitude of the first optimal read voltage to the history table; and
a read operation controller configured to provide a read command to read data stored in the first sub-block, the first optimal read offset, and the first optimal read pass offset to the nonvolatile memory device in response to a read request for the first sub-block.

17. The storage controller of claim 16,
wherein the read level controller is configured to determine a second optimal read voltage of a second sub-block among the plurality of sub-blocks based on a result of the OVS operation performed on the second sub-block, and add a second optimal read offset and a second optimal read pass offset corresponding to a magnitude of the second optimal read voltage to the history table, and
wherein the read operation controller is configured to provide the second optimal read offset to the nonvolatile memory device in response to the read request.

18. The storage controller of claim 16, wherein the read operation controller is configured to identify a third sub-block corresponding to an open block among the plurality of sub-blocks in response to the read request, and provide a last program address of the third sub-block and an open read pass offset for a voltage to be applied to open word lines of the third sub-block the third sub-block to the nonvolatile memory device.

19. The storage controller of claim 17,
wherein the read level controller is configured to set the magnitude of the first optimal read pass offset to be less than the magnitude of the second optimal read offset based on a magnitude of the first optimal read voltage being greater than a magnitude of the second optimal read voltage, and
wherein the read level controller is configured to set the magnitude of the first optimal read pass offset to be greater than the magnitude of the second optimal read offset based on the magnitude of the first optimal read voltage being less than the magnitude of the second optimal read voltage.

20. The storage controller of claim 16, wherein the read operation controller is configured to control the nonvolatile memory device to perform the OVS operation on the first sub-block based on a failure of an error correction operation performed on data read from the first sub-block.
